(19) United States
(12) Patent Application Publication
(10) Pub. No.: US 2022/0140250 A1
(43) Pub. Date: May 5, 2022

(54) LIGHT-EMITTING DEVICE, LIGHT-EMITTING APPARATUS, ELECTRONIC DEVICE, DISPLAY DEVICE, AND LIGHTING DEVICE

(71) Applicant: SEMICONDUCTOR ENERGY LABORATORY CO., LTD., Atsugi-shi (JP)

(72) Inventors: Yuta KAWANO, Yokohama (JP); Takeyoshi WATABE, Atsugi (JP); Airi UEDA, Sagamihara (JP); Nobuharu OHSAWA, Zama (JP); Keito TOSU, Isehara (JP); Harue OSAKA, Atsugi (JP); Ryo NARUKAWA, Hadano (JP); Satoshi SEO, Sagamihara (JP)

(21) Appl. No.: 17/516,826

(22) Filed: Nov. 2, 2021

(30) Foreign Application Priority Data
Nov. 5, 2020 (JP) 2020-184898

(51) Int. Cl. H01L 51/00

(52) U.S. Cl. CPC H01L 51/0067; H01L 51/0072; H01L 51/5056; H01L 51/0077; H01L 51/0073

(57) ABSTRACT

A novel light-emitting device, a novel light-emitting apparatus, a novel electronic device, a novel display device, and a novel lighting device which are highly convenient, useful, or reliable are provided. The light-emitting device includes a first electrode, a second electrode, a first layer, and a second layer. The second electrode includes a region overlapping with the first electrode, the first layer includes a region sandwiched between the first electrode and the second electrode, the first layer includes a light-emitting material, the light-emitting material has a function of emitting photoluminescent light in a solution, the photoluminescent light has a first spectrum, the first spectrum has a maximum peak at a wavelength λ1, and the wavelength λ1 is in the range greater than or equal to 440 nm and less than or equal to 470 nm. The second layer includes a region sandwiched between the first layer and the second electrode, the second layer includes a first organic compound, the first organic compound has a first refractive index n1 with respect to light having the wavelength λ1, and the first refractive index n1 is more than or equal to 1.4 and less than or equal to 1.75.

### BACKGROUND OF THE INVENTION

### 1. Field of the Invention

One embodiment of the present invention relates to a light-emitting device, a light-emitting apparatus, an electronic device, a display device, a lighting device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting apparatus, a power storage device, a memory device, a method for driving any of them, and a method for manufacturing any of them.

### 2. Description of the Related Art

Light-emitting devices (organic EL devices) including organic compounds and utilizing electroluminescence (EL) have been put to more practical use. In the basic structure of such light-emitting devices, an organic compound layer including a light-emitting material (an EL layer) is sandwiched between a pair of electrodes. Carriers (holes and electrons) are injected by application of voltage to the device, and recombination energy of the carriers is used, whereby light emission can be obtained from the light-emitting material.

Such light-emitting devices are of self-luminous type and thus have advantages over liquid crystal displays, such as high visibility and no need for backlight when used as pixels of a display, and are suitable as flat panel display devices. Displays including such light-emitting devices are also highly advantageous in that they can be thin and lightweight. Moreover, such light-emitting devices also have a feature that response speed is extremely fast.

Since light-emitting layers of such light-emitting devices can be successively formed two-dimensionally, planar light emission can be achieved. This feature is difficult to realize with point light sources typified by incandescent lamps or LEDs or linear light sources typified by fluorescent lamps; thus, such light-emitting devices also have great potential as planar light sources, which can be applied to lighting devices and the like.

Displays or lighting devices including light-emitting devices are suitable for a variety of electronic devices as described above, and research and development of light-emitting devices have progressed for better characteristics.

Low outcoupling efficiency is often a problem in an organic EL device. In particular, the attenuation due to reflection which is caused by a difference in refractive index between adjacent layers is a main cause of a reduction in device efficiency. In order to reduce this effect, a structure including a layer formed using a low refractive index material in an EL layer (see Patent Document 1, for example) has been proposed.

A light-emitting device having this structure can have higher outcoupling efficiency and higher external quantum efficiency than a light-emitting device having a conventional structure; however, it is not easy to form such a layer with a low refractive index in an EL layer without adversely affecting other critical characteristics of the light-emitting device. This is because a low refractive index is in a trade-off relationship with a high carrier-transport property or high reliability of a light-emitting device including a layer with a low refractive index. This problem is caused because the carrier-transport property and reliability of an organic compound largely depend on an unsaturated bond, and an organic compound having many unsaturated bonds tends to have a high refractive index.

### REFERENCE

### Patent Document

[Patent Document 1] United States Patent Application Publication No. 2020/0176692

### SUMMARY OF THE INVENTION

An object of one embodiment of the present invention is to provide a novel light-emitting device that is highly convenient, useful, or reliable. Another object is to provide a novel electronic device that is highly convenient, useful, or reliable. Another object is to provide a novel display device that is highly convenient, useful, or reliable. Another object is to provide a novel lighting device that is highly convenient, useful, or reliable. Another object is to provide a novel light-emitting device, a novel light-emitting apparatus, a novel electronic device, a novel display device, a novel lighting device, or a novel semiconductor device.

Note that the description of these objects does not preclude the existence of other objects. In one embodiment of the present invention, there is no need to achieve all these objects. Other objects will be apparent from and can be derived from the description of the specification, the drawings, the claims, and the like.

(1) One embodiment of the present invention is a light-emitting device including a first electrode, a second electrode, and a unit.

The second electrode includes a region overlapping with the first electrode, the unit includes a region sandwiched between the first electrode and the second electrode, and the unit includes a first layer and a second layer.

The first layer includes a region sandwiched between the first electrode and the second electrode, and the first layer includes a light-emitting material.

The light-emitting material has a function of emitting photoluminescent light in a solution. The photoluminescent light has a first spectrum ϕ1. The first spectrum ϕ1 has a maximum peak at a wavelength λ1. The wavelength λ1 is in a range greater than or equal to 440 nm and less than or equal to 470 nm.

The second layer includes a region sandwiched between the first layer and the second electrode. The second layer includes a first organic compound ETM.

The first organic compound ETM has a first refractive index n1 with respect to light having the wavelength λ1. The first refractive index n1 is more than or equal to 1.4 and less than or equal to 1.75.

Thus, light emitted from the first layer can be extracted efficiently. Blue light can be extracted efficiently. As a result, a novel light-emitting device that is highly convenient, useful, or reliable can be provided.

(2) One embodiment of the present invention is the above-described light-emitting device, in which the first spectrum ϕ1 has a full width at half maximum FWHM and in which the full width at half maximum FWHM is greater than or equal to 10 nm and less than or equal to 35 nm.

(3) One embodiment of the present invention is the above-described light-emitting device, in which the second electrode includes silver.

Thus, light emitted from the first layer can be extracted efficiently. Blue light can be extracted efficiently. Light with high saturation can be extracted efficiently. A microcavity structure can be formed using the second layer and the second electrode. The width of the spectrum of emitted light can be narrowed by using the microcavity structure. Light can be highly efficiently utilized even with the microcavity structure. As a result, a novel light-emitting device that is highly convenient, useful, or reliable can be provided.

(4) One embodiment of the present invention is the above-described light-emitting device, in which the first organic compound ETM is represented by General Formula (Gₑ₁2) below.

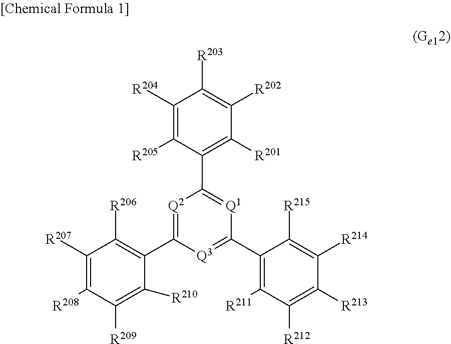

Note that two or three of Q¹ to Q³ are each a nitrogen atom. In the case where two of Q¹ to Q³ each represent a nitrogen atom, the remaining one of Q¹ to Q³ represents CH.

In the formula, at least one of R²⁰¹ to R²¹⁵ represents a phenyl group having a substituent, and the others of R²⁰¹ to R²¹⁵ each independently represent any of hydrogen, an alkyl group having 1 to 6 carbon atoms, an alicyclic hydrocarbon group having 3 to 10 carbon atoms, a substituted or unsubstituted aromatic hydrocarbon group having 6 to 14 carbon atoms in a ring, and a substituted or unsubstituted pyridyl group.

Furthermore, the phenyl group having a substituent has one or two substituents, and the substituents each independently represent any of an alkyl group having 1 to 6 carbon atoms, an alicyclic hydrocarbon group having 3 to 10 carbon atoms, and a substituted or unsubstituted aromatic hydrocarbon group having 6 to 14 carbon atoms in a ring.

(5) One embodiment of the present invention is the above-described light-emitting device, in which the first organic compound ETM includes sp³ carbon atoms, in which the sp³ carbon atoms each form a bond with other atoms by sp³ hybrid orbitals, and in which the sp³ carbon atoms account for higher than or equal to 10% and lower than or equal to 60% of total carbon atoms contained in the first organic compound.

Thus, light emitted from the first layer can be extracted efficiently. Blue light can be extracted efficiently. As a result, a novel light-emitting device that is highly convenient, useful, or reliable can be provided.

(6) One embodiment of the present invention is a light-emitting apparatus which includes the above-described light-emitting device and a transistor or a substrate.

(7) One embodiment of the present invention is a display device which includes the above-described light-emitting device and a transistor or a substrate.

(8) One embodiment of the present invention is a lighting device which includes the above-described light-emitting apparatus and a housing.

(9) One embodiment of the present invention is an electronic device which includes the above-described display device, a sensor, an operation button, a speaker, or a microphone.

Note that the light-emitting apparatus in this specification includes, in its category, an image display device that uses a light-emitting device. The light-emitting apparatus may also include a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

With one embodiment of the present invention, a novel light-emitting device that is highly convenient, useful, or reliable can be provided. A novel electronic device that is highly convenient, useful, or reliable can be provided. A novel display device that is highly convenient, useful, or reliable can be provided. A novel lighting device that is highly convenient, useful, or reliable can be provided. A novel light-emitting device, a novel light-emitting apparatus, a novel electronic device, a novel display device, a novel lighting device, or a novel semiconductor device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIGS. 1A to 1C illustrate a structure of a light-emitting device of an embodiment;

FIGS. 2A and 2B illustrate structures of light-emitting devices of embodiments;

FIG. 3 illustrates a structure of a functional panel of an embodiment;

FIGS. 4A to 4C illustrate structures of a functional panel of an embodiment;

FIGS. 5A and 5B are conceptual diagrams of an active matrix light-emitting apparatus;

FIGS. 6A and 6B are conceptual diagrams of active matrix light-emitting apparatuses;

FIG. 7 is a conceptual diagram of an active matrix light-emitting apparatus;

FIGS. 8A and 8B are conceptual diagrams of a passive matrix light-emitting apparatus;

FIGS. 9A and 9B illustrate a lighting device;

FIGS. 10A to 10D illustrate electronic devices;

FIGS. 11A to 11C illustrate electronic devices;

FIG. 12 illustrates a lighting device;

FIG. 13 illustrates a lighting device;

FIG. 14 illustrates in-vehicle display devices and lighting devices;

FIGS. 15A to 15C illustrate an electronic device;

FIG. 16 illustrates a structure of a light-emitting device of an example;

FIG. 17 is a graph showing an emission spectrum of a light-emitting material of an example;

FIG. 18 is a graph showing wavelength-refractive index characteristics of organic compounds ETM of examples;

FIG. 19 is a graph showing current density-luminance characteristics of light-emitting devices of an example;

FIG. 20 is a graph showing luminance-current efficiency characteristics of light-emitting devices of an example;

FIG. 21 is a graph showing voltage-luminance characteristics of light-emitting devices of an example;

FIG. 22 is a graph showing voltage-current characteristics of light-emitting devices of an example;

FIG. 23 is a graph showing luminance-blue index characteristics of light-emitting devices of an example;

FIG. 24 is a graph showing emission spectra of light-emitting devices of an example;

FIG. 25 illustrates a structure of a light-emitting device of an example;

FIG. 26 is a graph showing emission spectra of light-emitting materials of an example; and

FIG. 27 is a graph showing wavelength-refractive index characteristics and wavelength-reflectivity characteristics of materials of an example.

### DETAILED DESCRIPTION OF THE INVENTION

A light-emitting device of one embodiment of the present invention includes a first electrode, a second electrode, a first layer, and a second layer. The second electrode includes a region overlapping with the first electrode, the first layer includes a region sandwiched between the first electrode and the second electrode, and the second layer includes a region sandwiched between the first layer and the second electrode. The first layer includes a light-emitting material, the light-emitting material emits photoluminescent light, the photoluminescent light has a first spectrum, the first spectrum has a maximum peak at a wavelength λ1, and the wavelength λ1 is in a range greater than or equal to 440 nm and less than or equal to 470 nm. The second layer includes a first organic compound ETM, the first organic compound ETM has a first refractive index n1 with respect to light having the wavelength λ1, and the first refractive index n1 is more than or equal to 1.4 and less than or equal to 1.75.

Thus, light emitted from the first layer can be extracted efficiently. Blue light can be extracted efficiently. As a result, a novel light-emitting device that is highly convenient, useful, or reliable can be provided.

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments and examples. Note that in structures of the invention described below, the same portions or portions having similar functions are denoted by the same reference numerals in different drawings, and the description thereof is not repeated.

### Embodiment 1

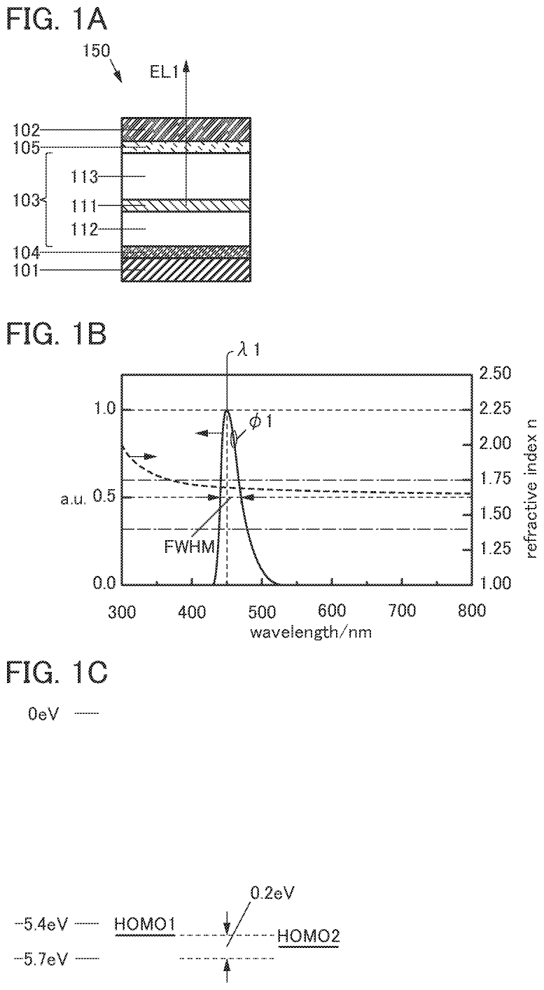

In this embodiment, a structure of a light-emitting device 150 of one embodiment of the present invention is described with reference to FIG. 1A to FIG. 1C.

FIG. 1A is a cross-sectional view illustrating a structure of a light-emitting device of one embodiment of the present invention, and FIG. 1B shows an emission spectrum and wavelength-refractive index characteristics in the structure of the light-emitting device of one embodiment of the present invention. FIG. 1C illustrates the structure of the light-emitting device of one embodiment of the present invention.

### <Structure Example 1 of Light-Emitting Device 150>

The light-emitting device 150 described in this embodiment includes an electrode 101, an electrode 102, and a unit 103 (see FIG. 1A).

The electrode 102 includes a region overlapping with the electrode 101, and the unit 103 includes a region sandwiched between the electrode 101 and the electrode 102.

### <Structure Example 1 of Unit 103>

The unit 103 includes a layer 111 and a layer 113. The unit 103 has a function of emitting light EL1.

For example, a layer selected from functional layers such as a light-emitting layer, a hole-transport layer, an electron-transport layer, and a carrier-blocking layer can be used for the unit 103. A layer selected from functional layers such as a hole-injection layer, an electron-injection layer, an exciton-blocking layer, and a charge-generation layer can also be used for the unit 103.

### «Structure Example 1 of Layer 111»

The layer 111 includes a region sandwiched between the electrode 101 and the electrode 102.

For example, a light-emitting material can be used for the layer 111. Note that the layer 111 can be referred to as a light-emitting layer. The layer 111 is preferably provided in a region where holes and electrons are recombined. This allows energy generated by recombination of carriers to be efficiently converted into light and emitted. Further, the layer 111 is preferably provided to be distanced from metals used as the electrodes or the like. This can inhibit a quenching phenomenon caused by the metals used as the electrodes or the like.

### [Example 1 of Light-Emitting Material]

A material that emits photoluminescent light can be used as the light-emitting material.

Note that the photoluminescent light has a spectrum ϕ1 having a maximum peak at a wavelength λ1 (see FIG. 1B). Note that the wavelength λ1 is in the range greater than or equal to 440 nm and less than or equal to 470 nm. Photoluminescence from the light-emitting material can be observed, for example, in a state where the light-emitting material is dissolved in a solvent. For example, photoluminescence from the light-emitting material can be observed in a state where the light-emitting material is dissolved in a polar solvent, a non-polar solvent, water, or the like. Specifically, toluene, dichloromethane, acetonitrile, or the like can be used as the solvent. In particular, toluene can be suitably used.

Examples of the light-emitting material include a material having a diazabora-naphthoanthracene skeleton, such as 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), and a material having a naphthobenzofuran skeleton, such as 3,10-bis[N-(dibenzofuran-3-yl)-N-phenylamino]naphtho[2,3-b;6,7-b′]bisbenzofuran (abbreviation: 3,10FrA2Nbf(IV)-02) or 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02).

### [Example 2 of Light-Emitting Material]

The light-emitting material emits phosphorescent light having the spectrum ϕ1 (see FIG. 1B). Note that the spectrum ϕ1 has a full width at half maximum FWHM which is greater than or equal to 10 nm and less than or equal to 35 nm.

Examples of the light-emitting material include a material having a diazabora-naphthoanthracene skeleton, such as 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), and a material having a naphthobenzofuran skeleton, such as 3,10-bis[N-(dibenzofuran-3-yl)-N-phenylamino]naphtho[2,3-b;6,7-b′]bisbenzofuran (abbreviation: 3,10FrA2Nbf(IV)-02) or 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02).

### «Structure Example 2 of Layer 111»

A carrier-transport material can be used as the host material. For example, a hole-transport material, an electron-transport material, a substance that exhibits thermally activated delayed fluorescence (TADF), a material having an anthracene skeleton, a mixed material, or the like can be used as the host material. It is preferable to use, as the host material, a material having a wider bandgap than the light-emitting material included in the layer 111. Thus, transfer of energy from excitons generated in the layer 111 to the host material can be suppressed.

### [Hole-Transport Material]

A material having a hole mobility of 1×10⁻⁶ cm²/Vs or higher can be suitably used as the hole-transport material.

For example, an amine compound or an organic compound having a π-electron rich heteroaromatic ring skeleton can be used as the hole-transport material. Specifically, a compound having an aromatic amine skeleton, a compound having a carbazole skeleton, a compound having a thiophene skeleton, a compound having a furan skeleton, or the like can be used. In particular, the compound having an aromatic amine skeleton or the compound having a carbazole skeleton are preferable because these compounds are highly reliable and have high hole-transport properties to contribute to a reduction in driving voltage.

### [Electron-Transport Material]

For example, a metal complex or an organic compound having a π-electron deficient heteroaromatic ring skeleton can be used as the electron-transport material.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

### [Material Having Anthracene Skeleton]

An organic compound having an anthracene skeleton can be used as the host material. In particular, when a fluorescent substance is used as the light-emitting substance, an organic compound having an anthracene skeleton is preferable. Thus, a light-emitting device with high emission efficiency and high durability can be achieved.

Among the organic compounds having an anthracene skeleton, an organic compound having a diphenylanthracene skeleton, in particular, a substance having a 9,10-diphenylanthracene skeleton, is chemically stable and thus is preferably used. The host material preferably has a carbazole skeleton in order to improve the hole-injection and hole-transport properties. In particular, the host material preferably has a dibenzocarbazole skeleton because the HOMO level thereof is shallower than that of carbazole by approximately 0.1 eV, so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferably used as the host material.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

### [Structure Example 1 of Mixed Material]

A material in which a plurality of kinds of substances are mixed can be used as the host material. For example, an electron-transport material and a hole-transport material can be used in the mixed material. In the mixed material, the weight ratio of the hole-transport material to the electron-transport material can be 1:19 to 19:1. Thus, the carrier-transport property of the layer 111 can be easily adjusted and a recombination region can be easily controlled.

### «Structure Example 1 of Layer 113»

The layer 113 includes a region sandwiched between the layer 111 and the electrode 102.

For example, a material having an electron-transport property, a material having an anthracene skeleton, a mixed material, or the like can be used for the layer 113. The layer 113 can be referred to as an electron-transport layer. A material having a wider bandgap than the light-emitting material included in the layer 111 is preferably used for the layer 113. Thus, transfer of energy from excitons generated in the layer 111 to the layer 113 can be inhibited.

### [Electron-Transport Material]

For example, a metal complex or an organic compound having a π-electron deficient heteroaromatic ring skeleton can be used as the electron-transport material.

As the electron-transport material, a material having an electron mobility higher than or equal to 1×10⁻⁷ cm²/Vs and lower than or equal to 5×10⁻⁵ cm²/Vs when the square root of the electric field strength [V/cm] is 600 can be suitably used. In this case, the electron-transport property in the electron-transport layer can be suppressed, the amount of electrons injected into the light-emitting layer can be controlled, or the light-emitting layer can be prevented from having excess electrons.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

### [Material Having Anthracene Skeleton]

An organic compound having an anthracene skeleton can be used for the layer 113. In particular, an organic compound having both an anthracene skeleton and a heterocyclic skeleton can preferably be used.

For example, it is possible to use an organic compound having both an anthracene skeleton and a nitrogen-containing five-membered ring skeleton. Alternatively, it is possible to use an organic compound having both an anthracene skeleton and a nitrogen-containing five-membered ring skeleton where two heteroatoms are included in a ring. Specifically, it is preferable to use, as the heterocyclic skeleton, a pyrazole ring, an imidazole ring, an oxazole ring, a thiazole ring, or the like.

For example, it is possible to use an organic compound having both an anthracene skeleton and a nitrogen-containing six-membered ring skeleton. Alternatively, it is possible to use an organic compound having both an anthracene skeleton and a nitrogen-containing six-membered ring skeleton where two heteroatoms are included in a ring. Specifically, it is preferable to use, as the heterocyclic skeleton, a pyrazine ring, a pyrimidine ring, a pyridazine ring, or the like.

### [Structure Example of Mixed Material]

A material in which a plurality of kinds of substances are mixed can be used for the layer 113. Specifically, a mixed material which includes an alkali metal, an alkali metal compound, or an alkali metal complex and an electron-transport substance can be used for the layer 113. Note that the electron-transport material preferably has a HOMO level of −6.0 eV or higher.

The mixed material can be suitably used for the layer 113 in combination with a structure using a composite material for a layer 104. For example, a composite material of an acceptor substance and a hole-transport material can be used for the layer 104. Specifically, a composite material of an acceptor substance and a substance having a relatively deep HOMO level (HOMO1), which is greater than or equal to −5.7 eV and lower than or equal to −5.4 eV, can be used for the layer 104 (see FIG. 1C). Using the mixed material for the layer 113 in combination with the structure using such a composite material for the layer 104 leads to an increase in the reliability of the light-emitting device.

Furthermore, a structure using a hole-transport material for a layer 112 is preferably combined with the structure using the mixed material for the layer 113 and the composite material for the layer 104. For example, a substance having a HOMO level (HOMO2), which is within the range of −0.2 eV to 0 eV, inclusive, from the above-described relatively deep HOMO level (HOMO1), can be used for the layer 112 (see FIG. 1C). This leads to an increase in the reliability of the light-emitting device.

The concentration of the alkali metal, the alkali metal compound, or the alkali metal complex preferably differs in the thickness direction of the layer 113 (including the case where the concentration is 0).

For example, a metal complex having a 8-hydroxyquinolinato structure can be used. A methyl-substituted product of the metal complex having a 8-hydroxyquinolinato structure (e.g., a 2-methyl-substituted product or a 5-methyl-substituted product) or the like can also be used.

As the metal complex having a 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### «Structure Example 2 of Layer 113»

The layer 113 includes an organic compound ETM. The organic compound ETM has a refractive index n1 with respect to light having the wavelength λ1, and the refractive index n1 is more than or equal to 1.4 and less than or equal to 1.75 (see FIG. 1B).

Thus, light emitted from the layer 111 can be extracted efficiently. Blue light can be extracted efficiently. As a result, a novel light-emitting device that is highly convenient, useful, or reliable can be provided.

Moreover, the reflectivity of the electrode 102 can be increased when a reflective metal such as silver is used in the electrode 102, for example. As a result, a novel light-emitting device that is highly convenient, useful, or reliable can be provided.

Furthermore, in the case where the electrode 102 has high reflectivity, using a light-emitting material having a function of emitting light that has an emission spectrum with a narrow full width at half maximum FWHM in the layer 111 enables light emitted from the layer 111 to be extracted efficiently.

Therefore, when the layer 111 includes a light-emitting material having a function of emitting light that has an emission spectrum with a narrow full width at half maximum FWHM and the layer 113 includes an organic compound with a low refractive index, a light-emitting device with high emission efficiency can be provided. In general, an organic compound has a refractive index with respect to light in a blue wavelength range higher than a refractive index with respect to light in a red wavelength range. Thus, using an organic compound with a low refractive index with respect to light in a blue wavelength range in the layer 113 is particularly useful in extracting blue light efficiently.

### [Example 1 of Organic Compound ETM]

As the organic compound ETM, a material which has an ordinary refractive index of more than or equal to 1.50 and less than or equal to 1.75 in a blue light emission range (455 nm to 465 nm) or an ordinary refractive index of more than or equal to 1.45 and less than or equal to 1.70 with respect to light of wavelength 633 nm, which is usually used for measurement of refractive indices, is preferably used.

In the case where the material has anisotropy, the refractive index with respect to an ordinary ray might differ from that with respect to an extraordinary ray. When a thin film to be measured is in such a state, anisotropy analysis can be performed to separately calculate the ordinary refractive index and the extraordinary refractive index. In this specification, when the measured material has both the ordinary refractive index and the extraordinary refractive index, the ordinary refractive index is used as an indicator.

An example of the organic compound ETM is an organic compound which includes at least one six-membered heteroaromatic ring having 1 to 3 nitrogen atoms; a plurality of aromatic hydrocarbon rings each having 6 to 14 carbon atoms in a ring, at least two of which are benzene rings; and a plurality of hydrocarbon groups forming a bond by sp³ hybrid orbitals.

In the above organic compound, a proportion of carbon atoms forming a bond by sp³ hybrid orbitals in total carbon atoms in molecules of the organic compound is preferably higher than or equal to 10% and lower than or equal to 60%, further preferably higher than or equal to 10% and lower than or equal to 50%. Alternatively, when the above organic compound is subjected to ¹H-NMR measurement, the integral value of signals at lower than 4 ppm is preferably ½ or more of the integral value of signals at 4 ppm or higher.

It is preferable that all the hydrocarbon groups forming a bond by sp³ hybrid orbitals in the above organic compound be bonded to the aromatic hydrocarbon rings each having 6 to 14 carbon atoms in a ring, and the LUMO of the organic compound not be distributed in the aromatic hydrocarbon rings.

### [Example 2 of Organic Compound ETM]

For example, an organic compound represented by General Formula (Gₑ₁1) below can be used as the organic compound ETM.

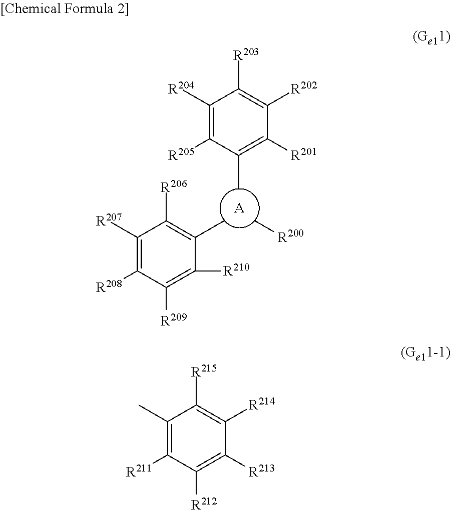

In the formula, A represents a six-membered heteroaromatic ring having 1 to 3 nitrogen atoms, and is preferably any of a pyridine ring, a pyrimidine ring, a pyrazine ring, a pyridazine ring, and a triazine ring.

In addition, R²⁰⁰ represents any of hydrogen, an alkyl group having 1 to 6 carbon atoms, an alicyclic group having 3 to 10 carbon atoms, and a substituent represented by Formula (Gₑ₁1-1).

At least one of R²⁰¹ to R²¹⁵ represents a phenyl group having a substituent and the others each independently represent any of hydrogen, an alkyl group having 1 to 6 carbon atoms, an alicyclic group having 3 to 10 carbon atoms, a substituted or unsubstituted aromatic hydrocarbon group having 6 to 14 carbon atoms in a ring, and a substituted or unsubstituted pyridyl group. Note that R²⁰¹, R²⁰³, R²⁰⁵, R²⁰⁶, R²⁰⁸, R²¹⁰, R²¹¹, R²¹³, and R²¹⁵ are preferably hydrogen. The phenyl group having a substituent has one or two substituents, which each independently represent any of an alkyl group having 1 to 6 carbon atoms, an alicyclic group having 3 to 10 carbon atoms, and a substituted or unsubstituted aromatic hydrocarbon group having 6 to 14 carbon atoms in a ring.

The organic compound represented by General Formula (Gₑ₁1) above has a plurality of hydrocarbon groups selected from an alkyl group having 1 to 6 carbon atoms and an alicyclic group having 3 to 10 carbon atoms, and a proportion of carbon atoms forming a bond by sp³ hybrid orbitals in total carbon atoms in molecules of the organic compound is higher than or equal to 10% and lower than or equal to 60%.

### [Example 3 of Organic Compound ETM]

For example, an organic compound represented by General Formula (Gₑ₁2) below can be used as the organic compound ETM.

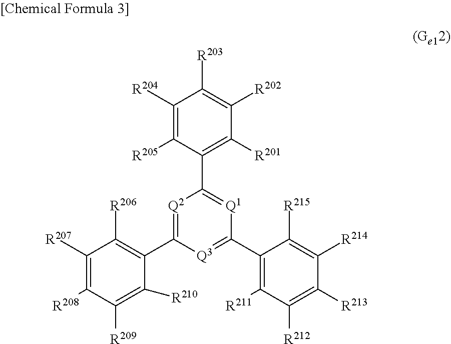

In the above general formula, two or three of Q¹ to Q³ are each a nitrogen atom. In the case where two of Q¹ to Q³ each represent a nitrogen atom, the remaining one thereof represents CH.

At least one of R²⁰¹ to R²¹⁵ represents a phenyl group having a substituent and the others of R²⁰¹ to R²¹⁵ each independently represent any of hydrogen, an alkyl group having 1 to 6 carbon atoms, an alicyclic hydrocarbon group having 3 to 10 carbon atoms, a substituted or unsubstituted aromatic hydrocarbon group having 6 to 14 carbon atoms in a ring, and a substituted or unsubstituted pyridyl group.

The phenyl group having a substituent has one or two substituents, which each independently represent any of an alkyl group having 1 to 6 carbon atoms, an alicyclic hydrocarbon group having 3 to 10 carbon atoms, and a substituted or unsubstituted aromatic hydrocarbon group having 6 to 14 carbon atoms in a ring.

### [Example 4 of Organic Compound ETM]

Furthermore, the organic compound represented by General Formula (Gₑ₁2) in which sp³ carbon atoms account for higher than or equal to 10% and lower than or equal to 60% of total carbon atoms contained in the organic compound can be used as the organic compound ETM, for example. Note that the sp³ carbon atom refers to carbon atom that forms a bond with other atoms by sp³ hybrid orbitals.

In the organic compound represented by General formula (Gₑ₁1) or (Gₑ₁2) above, the phenyl group having a substituent is preferably a group represented by Formula (Gₑ₁1-2) below.

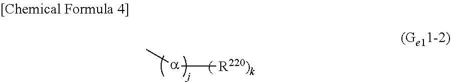

In the formula, α represents a substituted or unsubstituted phenylene group and is preferably a meta-substituted phenylene group. In the case where the meta-substituted phenylene group has a substituent, the substituent is also preferably meta-substituted. The substituent is preferably an alkyl group having 1 to 6 carbon atoms or an alicyclic group having 3 to 10 carbon atoms, further preferably an alkyl group having 1 to 6 carbon atoms, and still further preferably a t-butyl group.

R²²⁰ represents an alkyl group having 1 to 6 carbon atoms, an alicyclic group having 3 to 10 carbon atoms, or a substituted or unsubstituted aromatic hydrocarbon group having 6 to 14 carbon atoms in a ring.

In addition, j and k each represent 1 or 2. In the case where j is 2, a plurality of α may be the same or different from each other. In the case where k is 2, a plurality of R²²⁰ may be the same or different from each other. R²²⁰ is preferably a phenyl group, further preferably a phenyl group that has an alkyl group having 1 to 6 carbon atoms or an alicyclic group having 3 to 10 carbon atoms at one or both of the two meta-positons. The substituent at one or both of the two meta-positons of the phenyl group is preferably an alkyl group having 1 to 6 carbon atoms, further preferably a t-butyl group.

Thus, light emitted from the layer 111 can be extracted efficiently. Blue light can be extracted efficiently. As a result, a novel light-emitting device that is highly convenient, useful, or reliable can be provided.

### <Structure Example of Electrode 102>

A conductive material can be used in the electrode 102. Specifically, a metal, an alloy, a conductive compound, a mixture of these, or the like can be used in the electrode 102. For example, a material with a lower work function than the electrode 101 can be suitably used in the electrode 102. Specifically, a material with a work function of 3.8 eV or less is preferable.

For example, silver (Ag) or an alloy containing silver (e.g., MgAg) can be used in the electrode 102.

Thus, light emitted from the layer 111 can be extracted efficiently. Blue light can be extracted efficiently. Light with high saturation can be extracted efficiently. A microcavity structure can be formed using the layer 113 and the electrode 102. The width of the spectrum of emitted light can be narrowed by using the microcavity structure. Light can be highly efficiently utilized even with the microcavity structure. As a result, a novel light-emitting device that is highly convenient, useful, or reliable can be provided.

### <Structure Example 2 of Unit 103>

The unit 103 includes the layer 112. The layer 112 includes a region sandwiched between the electrode 101 and the layer 111 (see FIG. 1A).

### «Structure Example of Layer 112»

For example, a material having a hole-transport property can be used for the layer 112. The layer 112 can be referred to as a hole-transport layer. It is preferable to use, in the layer 112, a material having a wider bandgap than the light-emitting material included in the layer 111. Thus, transfer of energy from excitons generated in the layer 111 to the layer 112 can be suppressed.

### [Hole-Transport Material]

A material having a hole mobility of 1×10⁻⁶ cm²/Vs or higher can be suitably used as the hole-transport material.

For example, an amine compound or an organic compound having a π-electron rich heteroaromatic ring skeleton can be used as the hole-transport material. Specifically, a compound having an aromatic amine skeleton, a compound having a carbazole skeleton, a compound having a thiophene skeleton, a compound having a furan skeleton, or the like can be used. In particular, the compound having an aromatic amine skeleton or the compound having a carbazole skeleton are preferable because these compounds are highly reliable and have high hole-transport properties to contribute to a reduction in driving voltage.

The following are examples that can be used as the compound having an aromatic amine skeleton: 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBF3P-II), 4-(3-[3-(9-phenyl-9H-fluoren-9-yl)phenyl]phenyl)dibenzofuran (abbreviation: mmDBFFLBi-II), or the like can be used.

Note that this embodiment can be combined with any of the other embodiments in this specification as appropriate.

### Embodiment 2

In this embodiment, a structure of the light-emitting device 150 of one embodiment of the present invention is described with reference to FIGS. 1A to 1C.

### <Structure Example of Light-Emitting Device 150>

The light-emitting device 150 described in this embodiment includes the electrode 101, the electrode 102, the unit 103, and the layer 104. The electrode 102 includes a region overlapping with the electrode 101, and the unit 103 includes a region between the electrode 101 and the electrode 102. The layer 104 includes a region between the electrode 101 and the unit 103. For example, the structure described in Embodiment 1 can be employed for the unit 103.

### <Structure Example of Electrode 101>

For example, a conductive material can be used for the electrode 101. Specifically, a metal, an alloy, a conductive compound, and a mixture of these, or the like can be used for the electrode 101. For example, a material having a work function higher than or equal to 4.0 eV can be suitably used.

For example, indium oxide-tin oxide (ITO: indium tin oxide), indium oxide-tin oxide containing silicon or silicon oxide, indium oxide-zinc oxide, or indium oxide containing tungsten oxide and zinc oxide (IWZO) can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### «Structure Example of Layer 104»

A hole-injection material can be used for the layer 104, for example. The layer 104 can be referred to as a hole-injection layer.

Specifically, an acceptor substance can be used for the layer 104. Alternatively, a material in which an acceptor substance and a hole-transport material are combined can be used for the layer 104. This can facilitate the injection of holes from the electrode 101, for example. In addition, the driving voltage of the light-emitting device can be reduced.

### [Acceptor Substance]

An organic compound or an inorganic compound can be used as the acceptor substance. The acceptor substance can extract electrons from an adjacent hole-transport layer or a hole-transport material by the application of an electric field.

For example, a compound having an electron-withdrawing group (a halogen or cyano group) can be used as the acceptor substance. Note that an organic compound having an acceptor property is easily evaporated, which facilitates film deposition. Thus, the productivity of the light-emitting device can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the acceptor substance, a molybdenum oxide, a vanadium oxide, a ruthenium oxide, a tungsten oxide, a manganese oxide, or the like can be used.

It is possible to use any of the following materials: phthalocyanine-based complex compounds such as phthalocyanine (abbreviation: H₂Pc) and copper phthalocyanine (abbreviation: CuPc); and compounds each having an aromatic amine skeleton such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD).

In addition, high molecular compounds such as poly(3,4-ethylenedioxythiophene)/poly(styrenesulfonic acid)(abbreviation: PEDOT/PSS), and the like can be used.

### [Structure Example 1 of Composite Material]

A material composed of two or more kinds of substances can be used as the hole-injection material. For example, an acceptor substance and a hole-transport material can be used for the composite material. Accordingly, not only a material having a high work function but also a material having a low work function can also be used for the electrode 101. Alternatively, a material used for the electrode 101 can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material.

A substance having a relatively deep HOMO level can be suitably used for the hole-transport material in the composite material. Specifically, the HOMO level is preferably higher than or equal to −5.7 eV and lower than or equal to −5.4 eV. Accordingly, hole injection to the unit 103 can be facilitated. Hole injection to the layer 112 can be facilitated. The reliability of the light-emitting device can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As aromatic hydrocarbon having a vinyl skeleton, for example, 4,4′-bis(2,2-diphenylvinyl)biphenyl (abbreviation: DPVBi), or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used.

Furthermore, a substance having any of a carbazole derivative, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With use of a substance including an N,N-bis(4-biphenyl)amino group, the reliability of the light-emitting device can be increased.

Specific examples of the hole-transport material in the composite material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: TbBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### [Structure Example 2 of Composite Material]

For example, a composite material including an acceptor substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104 can be reduced. A layer with a low refractive index can be formed inside the light-emitting device. The external quantum efficiency of the light-emitting device can be improved.

Note that this embodiment can be combined with any of the other embodiments in this specification as appropriate.

### Embodiment 3

In this embodiment, a structure of the light-emitting device 150 of one embodiment of the present invention is described with reference to FIGS. 1A to 1C.

### <Structure Example of Light-Emitting Device 150>

The light-emitting device 150 described in this embodiment includes the electrode 101, the electrode 102, the unit 103, and a layer 105. The electrode 102 includes a region overlapping with the electrode 101, and the unit 103 includes a region between the electrode 101 and the electrode 102. The layer 105 includes a region between the unit 103 and the electrode 102. For example, the structure described in Embodiment 1 or Embodiment 2 can be employed for the unit 103.

### <Structure Example of Electrode 102>

For example, a conductive material can be used for the electrode 102. Specifically, a metal, an alloy, a conductive compound, a mixture of these, or the like can be used for the electrode 102. For example, a material with a lower work function than the electrode 101 can be suitably used for the electrode 102. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 102.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements such as MgAg or AlLi can be used for the electrode 102.

### «Structure Example of Layer 105»

An electron-injection material can be used for the layer 105, for example. The layer 105 can be referred to as an electron-injection layer.

Specifically, a donor substance can be used for the layer 105. Alternatively, a material in which a donor substance and an electron-transport material are combined can be used for the layer 105. Alternatively, electride can be used for the layer 105. This can facilitate the injection of electrons from the electrode 102, for example. Alternatively, not only a material having a low work function but also a material having a high work function can also be used for the electrode 102. Alternatively, a material used for the electrode 102 can be selected from a wide range of materials regardless of its work function. Specifically, Al, Ag, ITO, indium oxide-tin oxide containing silicon or silicon oxide, or the like can be used for the electrode 102. The driving voltage of the light-emitting device can be reduced.

### [Donor Substance]

For example, an alkali metal, an alkaline earth metal, a rare earth metal, or a compound thereof (an oxide, a halide, a carbonate, or the like) can be used for the donor substance. Alternatively, an organic compound such as tetrathianaphthacene (abbreviation: TTN), nickelocene, or decamethylnickelocene can be used as the donor substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material composed of two or more kinds of substances can be used as the electron-injection material. For example, a donor substance and an electron-transport material can be used for the composite material.

### [Electron-Transport Material]

For example, a metal complex or an organic compound having a π-electron deficient heteroaromatic ring skeleton can be used as the electron-transport material.

As the electron-transport material, a material having an electron mobility higher than or equal to 1×10⁻⁷ cm²/Vs and lower than or equal to 5×10⁻⁵ cm²/Vs when the square root of the electric field strength [V/cm] is 600 can be suitably used. In this case, the electron-transport property in the electron-transport layer can be suppressed, the amount of electrons injected into the light-emitting layer can be controlled, or the light-emitting layer can be prevented from having excess electrons.

As the metal complex, bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As the heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazolin (abbreviation: 4,8mDBtP2Bqn) can be used, for example.

As the heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As the heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-(3-[3-(benzo[b]naphtho[1,2-d]furan-8-yl)phenyl]phenyl)-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

### [Structure Example 2 of Composite Material]

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or an alkaline earth metal at 50 wt % or higher can be suitably used. Alternatively, a composite material including an organic compound having a bipyridine skeleton can be suitably used. Thus, the refractive index of the layer 104 can be reduced. The external quantum efficiency of the light-emitting device can be improved.

### [Electride]

For example, a substance obtained by adding electrons at high concentration to an oxide where calcium and aluminum are mixed can be used, for example, as the electron-injection material.

Note that this embodiment can be combined with any of the other embodiments in this specification as appropriate.

### Embodiment 4

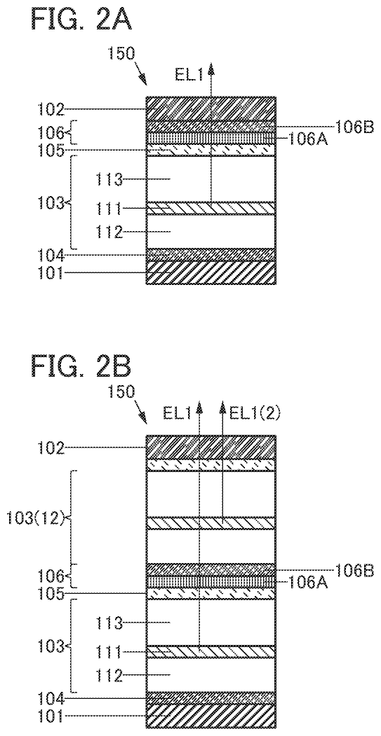

In this embodiment, a structure of the light-emitting device 150 of one embodiment of the present invention is described with reference to FIG. 2A.

FIG. 2A is a cross-sectional view illustrating a structure of a light-emitting device of one embodiment of the present invention.

### <Structure Example of Light-Emitting Device 150>

The light-emitting device 150 described in this embodiment includes the electrode 101, the electrode 102, the unit 103, and an intermediate layer 106 (see FIG. 2A). The electrode 102 includes a region overlapping with the electrode 101, and the unit 103 includes a region between the electrode 101 and the electrode 102. The intermediate layer 106 includes a region between the unit 103 and the electrode 102.

### «Structure Example of Intermediate Layer 106»

The intermediate layer 106 includes a layer 106A and a layer 106B. The layer 106B includes a region between the layer 106A and the electrode 102.

### «Structure Example of Layer 106A»

For example, an electron-transport material can be used for the layer 106A. The layer 106A can be referred to as an electron-relay layer. With the layer 106A, a layer that is on the anode side and in contact with the layer 106A can be distanced from a layer that is on the cathode side and in contact with the layer 106A. Interaction between the layer that is on the anode side and in contact with the layer 106A and the layer that is on the cathode side and in contact with the layer 106A can be reduced. Electrons can be smoothly supplied to the layer that is on the anode side and in contact with the layer 106A.

A substance whose LUMO level is positioned between the LUMO level of the acceptor substance included in the layer that is on the anode side and in contact with the layer 106A and the LUMO level of the substance included in the layer that is on the cathode side and in contact with the layer 106A can be suitably used for the layer 106A.

For example, a material having a LUMO level in a range higher than or equal to −5.0 eV, preferably higher than or equal to −5.0 eV and lower than or equal to −3.0 eV, can be used for the layer 106A.

Specifically, a phthalocyanine-based material can be used for the layer 106A. In addition, a metal complex having a metal-oxygen bond and an aromatic ligand can be used for the layer 106A.

### «Structure Example of Layer 106B»

For example, a material that supplies electrons to the anode side and supplies holes to the cathode side when voltage is applied can be used for the layer 106B. Specifically, electrons can be supplied to the unit 103 that is positioned on the anode side. The layer 106B can be referred to as a charge-generation layer.

Specifically, a hole-injection material capable of being used for the layer 104 can be used for the layer 106B. For example, a composite material can be used for the layer 106B. Alternatively, for example, a stacked film in which a film including the composite material and a film including a hole-transport material are stacked can be used for the layer 106B.

Note that this embodiment can be combined with any of the other embodiments in this specification as appropriate.

### Embodiment 5

In this embodiment, a structure of the light-emitting device 150 of one embodiment of the present invention is described with reference to FIG. 2B.

FIG. 2B is a cross-sectional view illustrating a structure of a light-emitting device of one embodiment of the present invention, which is different from that in FIG. 2A.

### <Structure Example of Light-Emitting Device 150>

The light-emitting device 150 described in this embodiment includes the electrode 101, the electrode 102, the unit 103, the intermediate layer 106, and a unit 103(12) (see FIG. 2B). The electrode 102 includes a region overlapping with the electrode 101, the unit 103 includes a region between the electrode 101 and the electrode 102, and the intermediate layer 106 includes a region between the unit 103 and the electrode 102. The unit 103(12) includes a region between the intermediate layer 106 and the electrode 102, and the unit 103(12) has a function of emitting light EL1(2).

A structure including the intermediate layer 106 and a plurality of units is referred to as a stacked light-emitting device or tandem light-emitting device in some cases. This structure enables high luminance emission while the current density is kept low. Reliability can be improved. The driving voltage can be reduced in comparison with that of the light-emitting device with the same luminance. The power consumption can be reduced.

### «Structure Example of Unit 103(12)»

The structure that can be employed for the unit 103 can also be employed for the unit 103(12). In other words, the light-emitting device 150 includes a plurality of units that are stacked. Note that the number of stacked units is not limited to two and may be three or more.

The same structure as the unit 103 can be employed for the unit 103(12). Alternatively, a structure different from the unit 103 can be employed for the unit 103(12).

For example, a structure which exhibits a different emission color from that of the unit 103 can be employed for the unit 103(12). Specifically, the unit 103 emitting red light and green light and the unit 103(12) emitting blue light can be employed. With this structure, a light-emitting device emitting light of a desired color can be provided. A light-emitting device emitting white light can be provided, for example.

### «Structure Example of Intermediate Layer 106»

The intermediate layer 106 has a function of supplying electrons to one of the unit 103 and the unit 103(12) and supplying holes to the other. For example, the intermediate layer 106 described in Embodiment 4 can be used.

### <Fabrication Method of Light-Emitting Device 150>

For example, each of the electrode 101, the electrode 102, the unit 103, the intermediate layer 106, and the unit 103(12) can be formed by a dry process, a wet process, an evaporation method, a droplet discharge method, a coating method, or a printing method. A formation method may differ between components of the device.

Specifically, the light-emitting device 150 can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. An indium oxide-zinc oxide film can be formed by a sputtering method using a target obtained by adding zinc oxide to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

Note that this embodiment can be combined with any of the other embodiments in this specification as appropriate.

### Embodiment 6

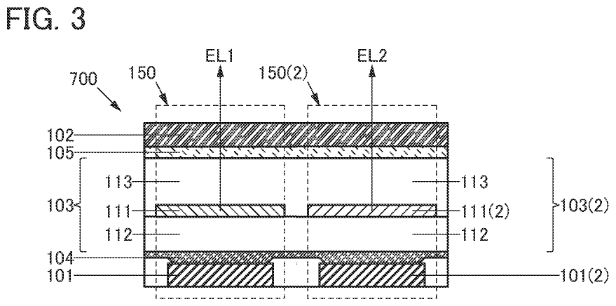

In this embodiment, a structure of a functional panel 700 of one embodiment of the present invention will be described with reference to FIG. 3.

### <Structure Example of Functional Panel 700>

The functional panel 700 described in this embodiment includes the light-emitting device 150 and a light-emitting device 150(2) (see FIG. 3).

For example, the light-emitting device described in any one of Embodiments 1 to 5 can be used as the light-emitting device 150.

### <Structure Example of Light-Emitting Device 150(2)>

The light-emitting device 150(2) described in this embodiment includes an electrode 101(2), the electrode 102, and a unit 103(2) (see FIG. 3). The electrode 102 includes a region overlapping with the electrode 101(2). Note that a component of the light-emitting device 150 can be used as a component of the light-emitting device 150(2). Thus, the component can be used in common. The fabrication process can be simplified.

### «Structure Example 1 of Unit 103(2)»

The unit 103(2) includes a region between the electrode 101(2) and the electrode 102. The unit 103(2) includes a layer 111(2).

The unit 103(2) has a single-layer structure or a stacked-layer structure. For example, the unit 103(2) can include a layer selected from functional layers such as a hole-transport layer, an electron-transport layer, a carrier-blocking layer, and an exciton-blocking layer.

The unit 103(2) includes a region where electrons injected from one of the electrodes recombine with holes injected from the other electrode. For example, a region where holes injected from the electrode 101(2) recombine with electrons injected from the electrode 102 is included.

### «Structure Example 1 of Layer 111(2)»

The layer 111(2) includes a light-emitting material and a host material. The layer 111(2) can be referred to as a light-emitting layer. Note that the layer 111(2) is preferably provided in a region where holes and electrons are recombined. Thus, energy generated by recombination of carriers can be efficiently converted into light and emitted. Furthermore, the layer 111(2) is preferably provided to be distanced from a metal used for the electrode or the like. Thus, a quenching phenomenon caused by the metal used for the electrode or the like can be inhibited.

For example, a light-emitting material different from the light-emitting material used for the layer 111 can be used for the layer 111(2). Specifically, a light-emitting material, whose emission color is different from the emission color of the light-emitting material used for the layer 111, can be used for the layer 111(2). Thus, light-emitting devices with different hues can be provided. A plurality of light-emitting devices with different hues can be used to perform additive color mixing. Alternatively, it is possible to express a color of a hue that an individual light-emitting device cannot display.

For example, a light-emitting device that emits blue light, a light-emitting device that emits green light, and a light-emitting device that emits red light can be provided in the functional panel 700. Alternatively, a light-emitting device that emits white light, a light-emitting device that emits yellow light, and a light-emitting device that emits infrared rays can be provided in the functional panel 700.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as light EL1 from the light-emitting material (see FIGS. 1A to 1C).

### [Fluorescent Substance]

A fluorescent substance can be used for the layer 111(2). For example, the following fluorescent substances can be used for the layer 111(2). Note that one embodiment of the present invention is not limited to this.

Specifically, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N″′,N″′-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-(2-[4-(dimethylamino)phenyl]ethenyl)-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-(2-isopropyl-6-[2-(1,1,7,7-tetramethyl-2,3,6,7-tetrahydro-1H,5H-benzo[ij]quinolizin-9-yl)ethenyl]-4H-pyran-4-ylidene)propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-(pyrene-1,6-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), or the like.

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, and high reliability.

### [Phosphorescent Substance]

A phosphorescent substance can be used for the layer 111(2). For example, phosphorescent substances described below as examples can be used for the layer 111(2). Note that one embodiment of the present invention is not limited to this.

Any of the following can be used for the layer 111(2): an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptzl-mp)₃]), tris(1-methyl-5-phenyl-3-propyl-1H-1,2,4-triazolato]iridium(III) (abbreviation: [Ir(Prptzl-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III)(abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), bis[2-(4′,6′-difluorophenyl)pyridinato-N,C^{2′}]iridium(III) acetylacetonate (abbreviation: Firacac), or the like can be used.

These substances are compounds exhibiting blue phosphorescence and having an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), or the like can be used.

Examples of a rare earth metal complex are tris(acetylacetonato) (monophenanthroline)terbium(III) (abbreviation: Tb(acac)₃(Phen)), and the like.

These are compounds that mainly exhibit green phosphorescence and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), bis[4,6-di(naphthalen-1-yl)pyrimidinato](dipivaloylmethanato)iridium(III) (abbreviation: Ir(dlpm)₂(dpm)), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: Ir(tppr)₂(dpm)), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

As a rare earth metal complex or the like, tris(1,3-diphenyl-1,3-propanedionato) (monophenanthroline)europium(III) (abbreviation: Eu(DBM)₃(Phen)), tris[1-(2-thenoyl)-3,3,3-trifluoroacetonato] (monophenanthroline)europium(III) (abbreviation: Eu(TTA)₃(Phen)), or the like can be used.

As a platinum complex or the like, 2,3,7,8,12,13,17,18-octaethyl-21H,23H-porphyrin platinum(II) (abbreviation: PtOEP) or the like can be used.

These compounds emit red phosphorescence having an emission peak at 600 nm to 700 nm. Furthermore, the organometallic iridium complexes having a pyrazine skeleton can provide red light emission with chromaticity favorably used for display devices.

### [Substance Exhibiting Thermally Activated Delayed Fluorescence (TADF)]

A TADF material can be used for the layer 111(2). For example, any of the TADF materials given below can be used as the light-emitting material. Note that one embodiment of the present invention is not limited to this.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, the following materials whose structural formulae are shown below can be used for example: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP).

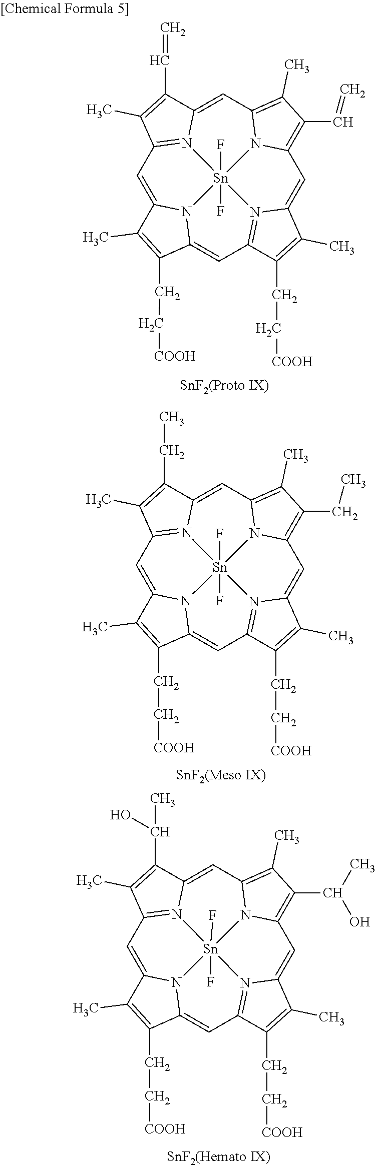

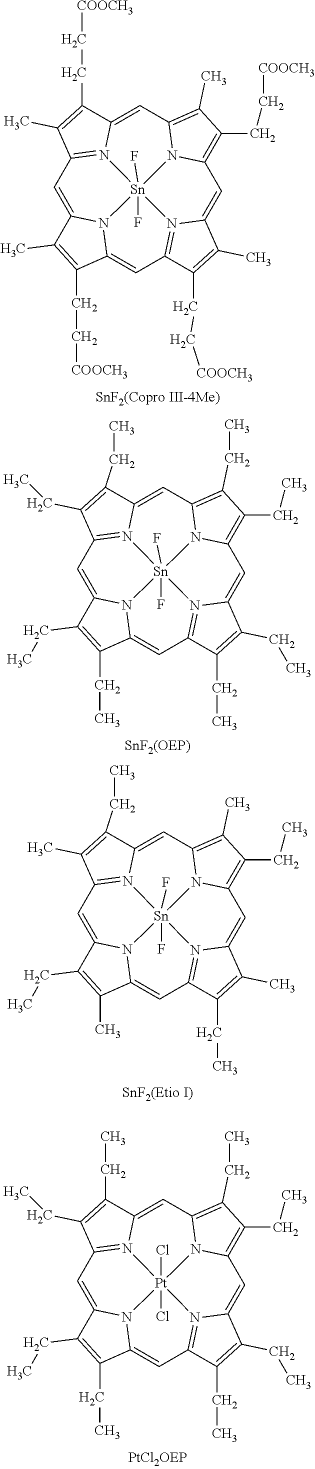

Furthermore, a heterocyclic compound including one or both of a π-electron rich heteroaromatic ring and a π-electron deficient heteroaromatic ring can be used, for example, for the TADF material.

Specifically, the following compounds whose structural formulae are shown below can be used for example: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), and 10-phenyl-10H,10′H-spiro[acridin-9,9′-anthracen]-10′-one (abbreviation: ACRSA).

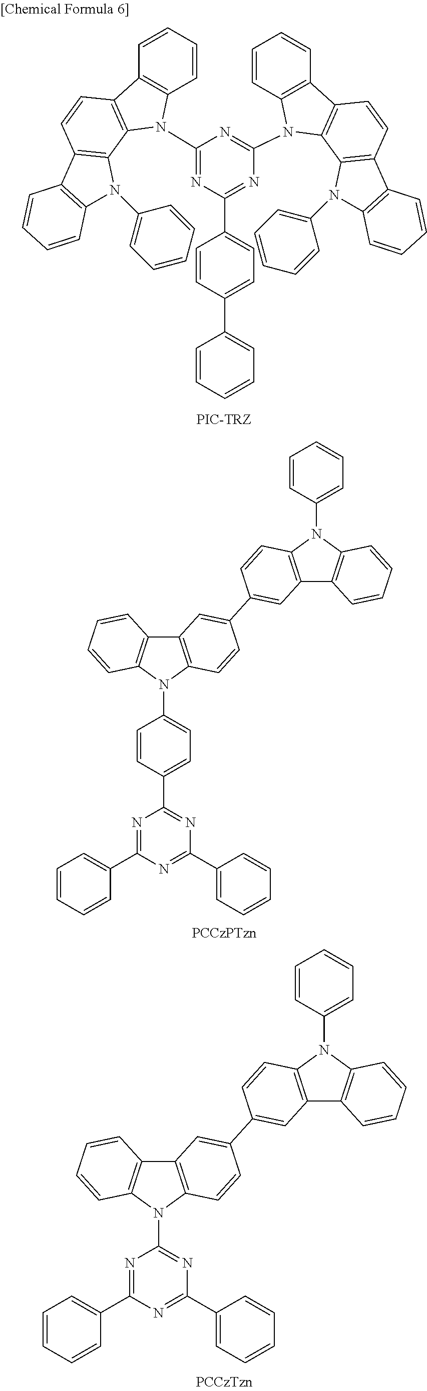 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

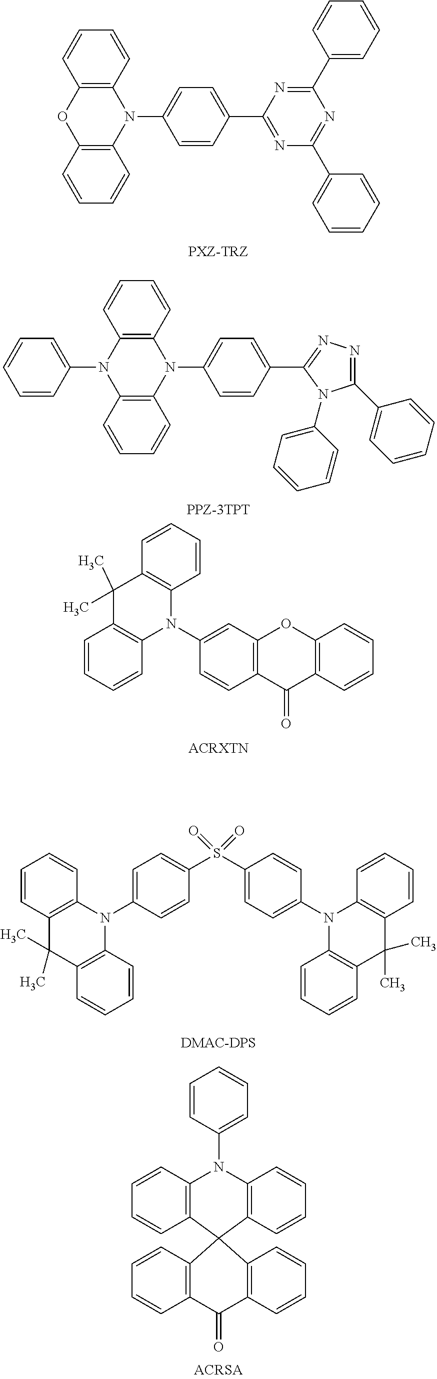 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### «Structure Example 2 of Layer 111(2)»

A carrier-transport material can be used as the host material. For example, a hole-transport material, an electron-transport material, a TADF material, a material having an anthracene skeleton, or a mixed material can be used as the host material. A material having a wider bandgap than the light-emitting material contained in the layer 111(2) is preferably used as the host material. Thus, transfer of energy from excitons generated in the layer 111(2) to the host material can be suppressed.

### [Hole-Transport Material]

A material having a hole mobility of 1×10⁻⁶ cm²/Vs or higher can be suitably used as the hole-transport material.

For example, a hole-transport material that can be used for the layer 112 can be used for the layer 111(2). Specifically, a hole-transport material that can be used for the hole-transport layer can be used for the layer 111(2).

For example, an electron-transport material that can be used for the layer 105 can be used for the layer 111(2). Specifically, an electron-transport material that can be used for the electron-injection layer can be used for the layer 111(2).

### [Material Having Anthracene Skeleton]

An organic compound having an anthracene skeleton can be used as the host material. In particular, when a fluorescent substance is used as the light-emitting substance, an organic compound having an anthracene skeleton is preferable. Thus, a light-emitting device with high emission efficiency and high durability can be achieved.

Among the organic compounds having an anthracene skeleton, an organic compound having a diphenylanthracene skeleton, in particular, a substance having a 9,10-diphenylanthracene skeleton, is chemically stable and thus is preferably used. The host material preferably has a carbazole skeleton in order to improve the hole-injection and hole-transport properties. In particular, the host material preferably has a dibenzocarbazole skeleton because the HOMO level thereof is shallower than that of carbazole by approximately 0.1 eV, so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferably used as the host material.

Examples of the substances that can be used include 6-[3-(9,10-diphenyl-2-anthryl)phenyl]-benzo[b]naphtho[1,2-d]furan (abbreviation: 2mBnfPPA), 9-phenyl-10-(4-(9-phenyl-9H-fluoren-9-yl)biphenyl-4′-yl)anthracene (abbreviation: FLPPA), 9-(1-naphthyl)-10-[4-(2-naphthyl)phenyl]anthracene (abbreviation: αN-βNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)-phenyl]-9-phenyl-9H-carbazole (abbreviation: PCPN), and the like.

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no a bond and a saturated hydrocarbon are preferably used. Specific examples include an alkyl group having 3 to 10, inclusive, carbon atoms, a substituted or unsubstituted cycloalkyl group having 3 to 10, inclusive, carbon atoms, and a trialkylsilyl group having 3 to 10, inclusive, carbon atoms. It is further preferable that the fluorescent substance have a plurality of protecting groups. The substituents having no a bond are poor in carrier-transport performance, whereby the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a a bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### [Structure Example 1 of Mixed Material]

A material in which a plurality of kinds of substances are mixed can be used as the host material. For example, an electron-transport material and a hole-transport material can be used in the mixed material. In the mixed material, the weight ratio of the hole-transport material to the electron-transport material can be 1:19 to 19:1. Thus, the carrier-transport property of the layer 111(2) can be easily adjusted and a recombination region can be easily controlled.

### [Structure Example 2 of Mixed Material]

In addition, a material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used as the host material. For example, a material in which an emission spectrum of a formed exciplex overlaps with a wavelength of the absorption band on the lowest energy side of the light-emitting substance can be used as the host material. This enables smooth energy transfer and improves emission efficiency. The driving voltage can be suppressed.

A phosphorescent substance can be used as at least one of the materials forming an exciplex. Accordingly, reverse intersystem crossing can be used. Triplet excitation energy can be efficiently converted into singlet excitation energy.

A combination of an electron-transport material and a hole-transport material having a HOMO level higher than or equal to that of the electron-transport material is preferable for forming an exciplex. The LUMO level of the hole-transport material is preferably higher than or equal to the LUMO level of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to a longer wavelength side than the emission spectra of each of the materials (or has another peak on the longer wavelength side) observed in comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has longer lifetime components or has a larger proportion of delayed components than that of each of the materials, observed in comparison of transient photoluminescence (PL) of the hole-transport material, the electron-transport material, and the mixed film of the materials. The transient PL can be rephrased as transient electroluminescence (EL). That is, the formation of an exciplex can also be confirmed by a difference in transient response observed in comparison of the transient EL of the hole-transport material, the electron-transport material, and the mixed film of the materials.

Note that this embodiment can be combined with any of the other embodiments in this specification as appropriate.

### Embodiment 7

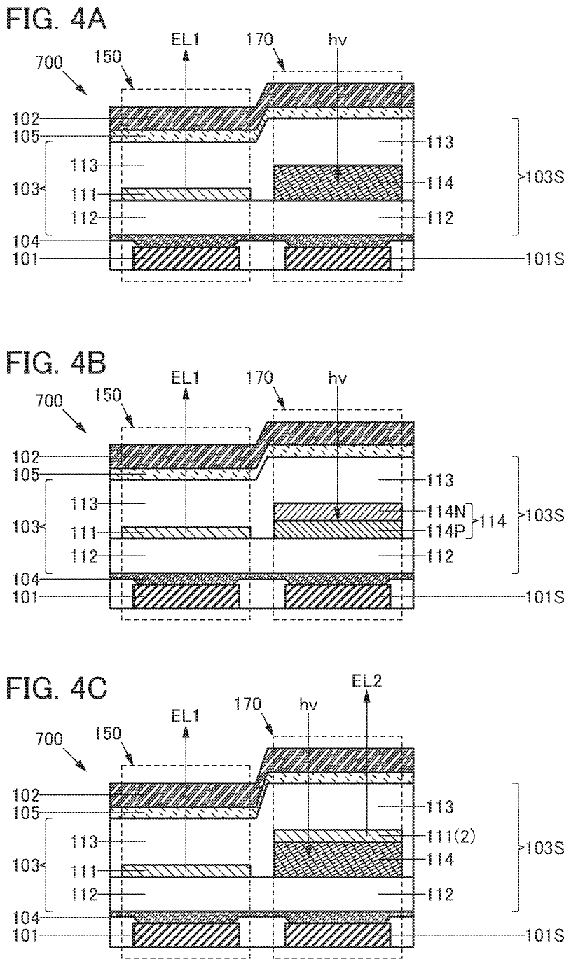

In this embodiment, a structure of the functional panel 700 of one embodiment of the present invention will be described with reference to FIGS. 4A to 4C.

### <Structure Example 1 of Functional Panel 700>

The functional panel 700 described in this embodiment includes the light-emitting device 150 and an optical device 170 (see FIG. 4A).

For example, the light-emitting device described in any one of Embodiments 1 to 5 can be used as the light-emitting device 150.

### <Structure Example of Optical Device 170>

The optical device 170 described in this embodiment includes an electrode 101S, the electrode 102, and a unit 103S. The electrode 102 includes a region overlapping with the electrode 101S, and the unit 103S includes a region between the electrode 101S and the electrode 102.

The optical device 170 includes the layer 104 and the layer 105. The layer 104 includes a region between the electrode 101S and the unit 103S, and the layer 105 includes a region between the unit 103S and the electrode 102. Note that a component of the light-emitting device 150 can be used as a component of the optical device 170. Thus, the component can be used in common. The fabrication process can be simplified.

### <Structure Example 1 of Unit 103S>

The unit 103S has a single-layer structure or a stacked-layer structure. The unit 103S includes a layer 114, the layer 112, and the layer 113, for example (see FIG. 4A).

The layer 114 includes a region between the layer 112 and the layer 113, the layer 112 includes a region between the electrode 101S and the layer 114, and the layer 113 includes a region between the electrode 102 and the layer 114.

The unit 103S can include, for example, a layer selected from functional layers such as a photoelectric conversion layer, a hole-transport layer, an electron-transport layer, and a carrier-blocking layer. The unit 103S can include a layer selected from functional layers such as an exciton-blocking layer and a charge-generation layer.

The unit 103S absorbs light hv, supplies electrons to one electrode, and supplies holes to the other. For example, the unit 103S supplies holes to the electrode 101S and supplies electrons to the electrode 102.

### «Structure Example of Layer 112»

A hole-transport material can be used for the layer 112, for example. The layer 112 can be referred to as a hole-transport layer. For example, the structure described in Embodiment 1 can be employed for the layer 112.

### «Structure Example of Layer 113»

An electron-transport material, a material having an anthracene skeleton, and a mixed material can be used for the layer 113, for example. For example, the structure described in Embodiment 1 can be employed for the layer 113.

### «Structure Example 1 of Layer 114»

For example, an electron-accepting material and an electron-donating material can be used for the layer 114. Specifically, a material that can be used for an organic solar cell can be used for the layer 114. In addition, the layer 114 can be referred to as a photoelectric conversion layer. The layer 114 absorbs the light hv, supplies electrons to one electrode, and supplies holes to the other. For example, the layer 114 supplies holes to the electrode 101S and supplies electrons to the electrode 102.

### [Example of Electron-Accepting Material]

As the electron-accepting material, a fullerene derivative or a non-fullerene electron acceptor can be used, for example.

As the electron-accepting material, a C₆₀ fullerene, a C₇₀ fullerene, [6,6]-phenyl-C₇₁-butyric acid methyl ester (abbreviation: PC71BM), [6,6]-phenyl-C₆₁-butyric acid methyl ester (abbreviation: PC61BM), 1′,1″,4′,4″-tetrahydro-di[1,4]methanonaphthaleno[1,2:2′,3′,56,60:2″,3″][5,6]fullerene-C₆₀ (abbreviation: ICBA), or the like can be used.

As the non-fullerene electron acceptor, a perylene derivative, a compound having a dicyanomethyleneindanone group, or the like can be used. For example, N,N′-dimethyl-3,4,9,10-perylenedicarboximide (abbreviation: Me-PTCDI) can be used.

### [Example of Electron-Donating Material]

As the electron-donating material, a phthalocyanine compound, a tetracene derivative, a quinacridone derivative, or a rubrene derivative can be used, for example.

As the electron-donating material, copper(II) phthalocyanine (abbreviation: CuPc), tin(II) phthalocyanine (SnPc), zinc phthalocyanine (ZnPc), tetraphenyldibenzoperiflanthene (DBP), rubrene, or the like can be used.

### «Structure Example 2 of Layer 114»

The layer 114 can have a single-layer structure or a stacked-layer structure, for example. Specifically, the layer 114 can have a bulk heterojunction structure. Alternatively, the layer 114 can have a heterojunction structure.

### [Structure Example of Mixed Material]

A mixed material containing an electron-accepting material and an electron-donating material can be used for the layer 114, for example. Note that a structure in which such a mixed material containing an electron-accepting material and an electron-donating material is used for the layer 114 can be referred to as a bulk heterojunction structure.

Specifically, a mixed material containing a C₇₀ fullerene and DBP can be used for the layer 114.

### [Example of Heterojunction Structure]

A layer 114N and a layer 114P can be used for the layer 114. The layer 114N includes a region between one electrode and the layer 114P, and the layer 114P includes a region between the layer 114N and the other electrode. For example, the layer 114N includes a region between the electrode 102 and the layer 114P, and the layer 114P includes a region between the layer 114N and the electrode 101S (see FIG. 4B).

An n-type semiconductor can be used for the layer 114N. For example, Me-PTCDI can be used for the layer 114N.

A p-type semiconductor can be used for the layer 114P. For example, rubrene can be used for the layer 114P.

Note that the optical device 170 in which the layer 114P is in contact with the layer 114N can be referred to as a pn-junction photodiode.

### <Structure Example 2 of Unit 103S>

The unit 103S includes the layer 111(2), and the layer 111(2) includes a region between the layer 114 and the layer 113 (see FIG. 4C).

Structure example 2 of the unit 103S is different from Structure example 1 of the unit 103S in that the layer 111(2) is provided. Different parts will be described in detail below, and the above description is referred to for parts having the same structure as the above.

### «Structure Example 3 of Layer 111(2)»

Either a structure containing a light-emitting material or a structure containing a light-emitting material and a host material can be employed for the layer 111(2), for example. The layer 111(2) can be referred to as a light-emitting layer. Note that the layer 111(2) is preferably provided in a region where holes and electrons are recombined. Thus, energy generated by recombination of carriers can be efficiently converted into light and emitted. Furthermore, the layer 111(2) is preferably provided to be distanced from a metal used for the electrode or the like. Thus, a quenching phenomenon caused by the metal used for the electrode or the like can be inhibited.

Specifically, the structure described in Embodiment 6 can be employed for the layer 111(2). In particular, the structure that emits light with a wavelength which is hardly absorbed by the layer 114 can be suitably employed for the layer 111(2). Accordingly, the light EL2 emitted from the layer 111(2) can be extracted with high efficiency.

Note that this embodiment can be combined with any of the other embodiments in this specification as appropriate.

### Embodiment 8

In this embodiment, a light-emitting apparatus including the light-emitting device described in any one of Embodiments 1 to 6 will be described.

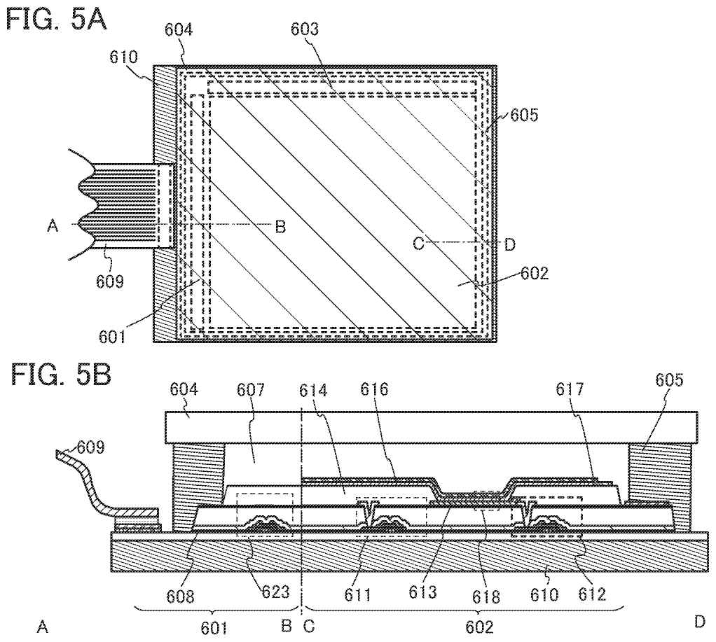

In this embodiment, the light-emitting apparatus fabricated using the light-emitting device described in any one of Embodiments 1 to 6 is described with reference to FIGS. 5A and 5B. Note that FIG. 5A is a top view of the light-emitting apparatus and FIG. 5B is a cross-sectional view taken along the lines A-B and C-D in FIG. 5A. This light-emitting apparatus includes a driver circuit portion (a source line driver circuit 601), a pixel portion 602, and another driver circuit portion (a gate line driver circuit 603), which are to control light emission of the light-emitting device and illustrated with dotted lines. Reference numeral 604 denotes a sealing substrate; 605, a sealing material; and 607, a space surrounded by the sealing material 605.

A lead wiring 608 is a wiring for transmitting signals to be input to the source line driver circuit 601 and the gate line driver circuit 603 and receives signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting apparatus in the present specification includes, in its category, not only the light-emitting apparatus itself but also the light-emitting apparatus provided with the FPC or the PWB.

Next, a cross-sectional structure is described with reference to FIG. 5B. The driver circuit portions and the pixel portion are formed over an element substrate 610; here, the source line driver circuit 601, which is a driver circuit portion, and one pixel in the pixel portion 602 are illustrated.

The element substrate 610 may be a substrate formed of glass, quartz, an organic resin, a metal, an alloy, or a semiconductor or a plastic substrate formed of fiber reinforced plastics (FRP), poly(vinyl fluoride) (PVF), polyester, an acrylic resin, or the like.

The structures of transistors used in pixels or driver circuits are not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, or gallium nitride can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable that a semiconductor having crystallinity be used, in which case deterioration of the transistor characteristics can be suppressed.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper or lower end portion. For example, in the case where a positive photosensitive acrylic resin is used for a material of the insulator 614, only the upper end portion of the insulator 614 preferably has a surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is desirably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, or a stack of three layers of a titanium nitride film, a film containing aluminum as its main component, and a titanium nitride film can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiments 1 to 6. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 passes through the second electrode 617, a stack including a thin metal film and a transparent conductive film (e.g., ITO, indium oxide containing zinc oxide at 2 wt % or higher and 20 wt % or lower, indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in any one of Embodiments 1 to 6. In the light-emitting apparatus of this embodiment, the pixel portion, which includes a plurality of light-emitting devices, may include both the light-emitting device described in any one of Embodiments 1 to 6 and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case degradation due to influence of moisture can be suppressed.

An epoxy-based resin or glass frit is preferably used for the sealing material 605. It is preferable that such a material not be permeable to moisture and oxygen as much as possible. As the sealing substrate 604, a glass substrate, a quartz substrate, or a plastic substrate formed of fiber reinforced plastics (FRP), poly(vinyl fluoride) (PVF), polyester, an acrylic resin, or the like can be used.

Although not illustrated in FIGS. 5A and 5B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, or indium oxide; a material containing aluminum nitride, hafnium nitride, silicon nitride, tantalum nitride, titanium nitride, niobium nitride, molybdenum nitride, zirconium nitride, or gallium nitride; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, or an oxide containing yttrium and zirconium can be used.

The protective film is preferably formed using a deposition method with favorable step coverage. One such method is an atomic layer deposition (ALD) method. A material that can be formed by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and rear surfaces of a touch panel.

As described above, the light-emitting apparatus fabricated using the light-emitting device described in any one of Embodiments 1 to 6 can be obtained.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

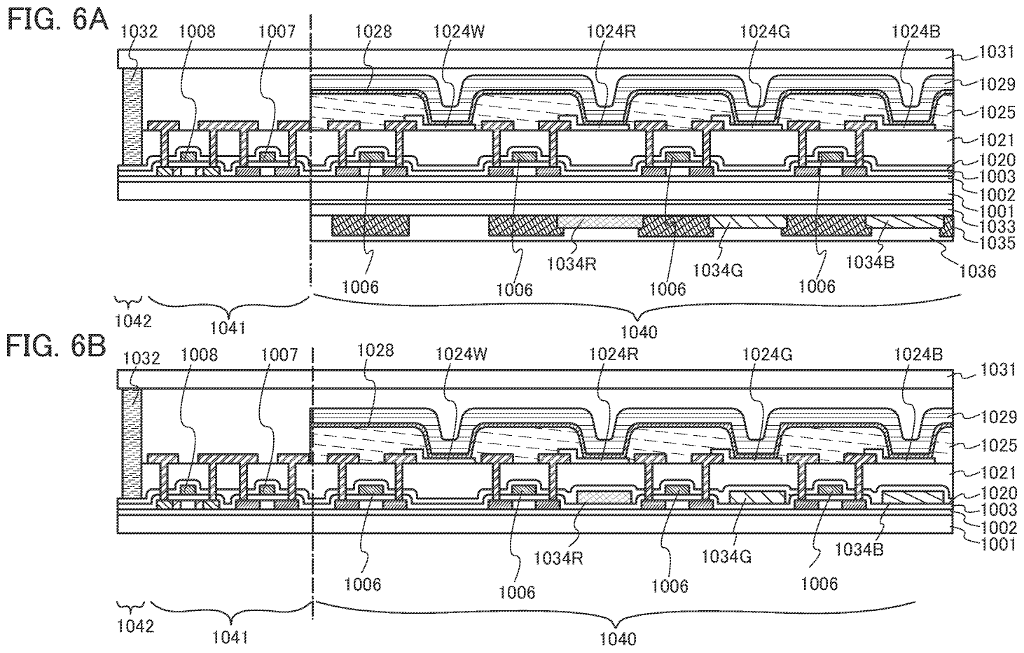

FIGS. 6A and 6B each illustrate an example of a light-emitting apparatus that includes a light-emitting device exhibiting white light emission, coloring layers (color filters), and the like to display a full-color image. In FIG. 6A, a substrate 1001, a base insulating film 1002, a gate insulating film 1003, a gate electrode 1006, a gate electrode 1007, and a gate electrode 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting devices, a partition 1025, an EL layer 1028, a second electrode 1029 of the light-emitting devices, a sealing substrate 1031, a sealing material 1032, and the like are illustrated.

In FIG. 6A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 6A, light emitted from part of the light-emitting layer does not pass through the coloring layers, while light emitted from the other part of the light-emitting layer passes through the coloring layers. The light that does not pass through the coloring layers is white and the light that passes through any one of the coloring layers is red, green, or blue; thus, an image can be displayed using pixels of the four colors.

FIG. 6B shows an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

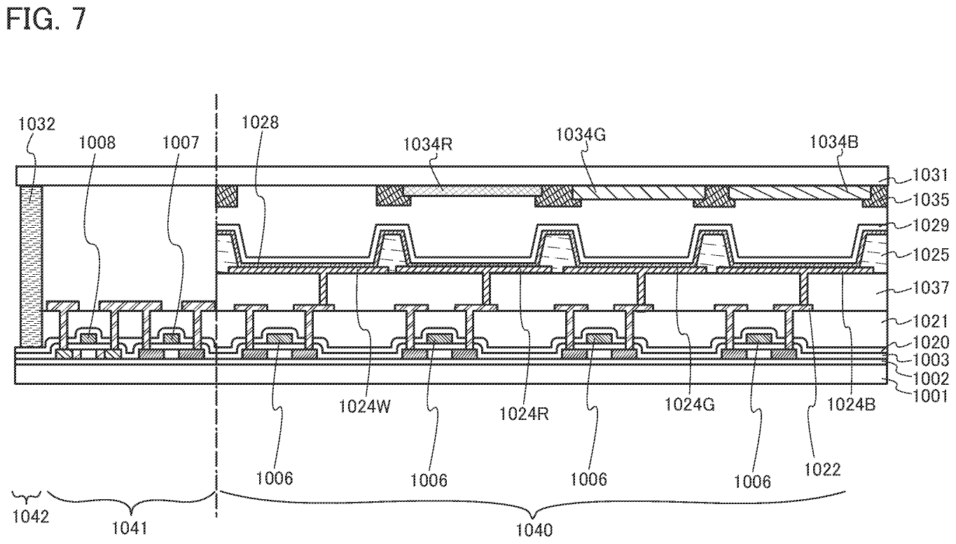

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 7 is a cross-sectional view of a light-emitting apparatus having a top emission structure. In this case, a substrate which does not transmit light can be used as the substrate 1001. The process up to the step of forming a connection electrode which connects the FET and the anode of the light-emitting device is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The first electrodes 1024W, 1024R, 1024G, and 1024B of the light-emitting devices each serve as an anode here, but may serve as a cathode. Furthermore, in the case of the top-emission light-emitting apparatus illustrated in FIG. 7, the first electrodes are preferably reflective electrodes. The EL layer 1028 is formed to have a structure similar to the structure of the unit 103, which is described in any one of Embodiments 1 to 6, with which white light emission can be obtained.

In the case of a top emission structure as illustrated in FIG. 7, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be favorably employed. A light-emitting device with a microcavity structure is formed with use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode has a visible light reflectivity higher than or equal to 40% and lower than or equal to 100%, preferably higher than or equal to 70% and lower than or equal to 100%, and a resistivity of 1×10⁻² Ωcm or lower. In addition, the semi-transmissive and semi-reflective electrode has a visible light reflectivity higher than or equal to 20% and lower than or equal to 80%, preferably higher than or equal to 40% and lower than or equal to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting device, by changing the thickness of the transparent conductive film, the composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem light-emitting device described above may be combined with a plurality of EL layers; for example, a light-emitting device may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

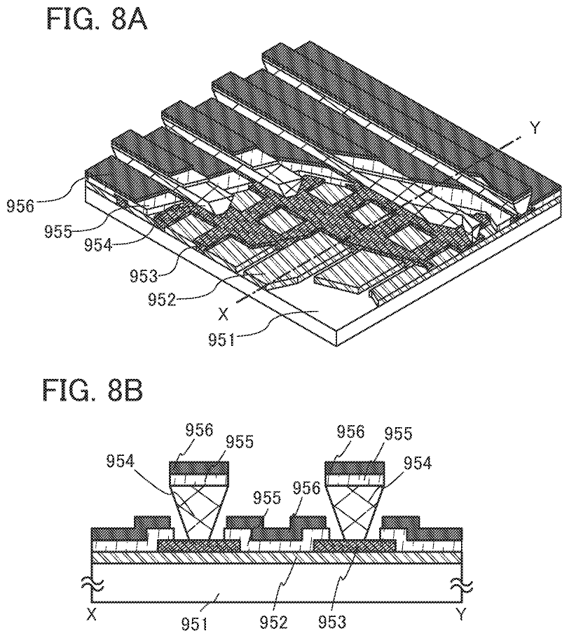

An active matrix light-emitting apparatus is described above, whereas a passive matrix light-emitting apparatus is described below. FIGS. 8A and 8B illustrate a passive matrix light-emitting apparatus manufactured using the present invention. Note that FIG. 8A is a perspective view of the light-emitting apparatus, and FIG. 8B is a cross-sectional view taken along the line X-Y in FIG. 8A. In FIGS. 8A and 8B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 thus provided can prevent defects in the light-emitting device due to static electricity or others. The passive-matrix light-emitting apparatus also includes the light-emitting device described in any one of Embodiments 1 to 6; thus, the light-emitting apparatus can have high reliability or low power consumption.

Since many minute light-emitting devices arranged in a matrix in the light-emitting apparatus described above can each be controlled, the light-emitting apparatus can be suitably used as a display device for displaying images.

This embodiment can be freely combined with any of the other embodiments.

### Embodiment 9

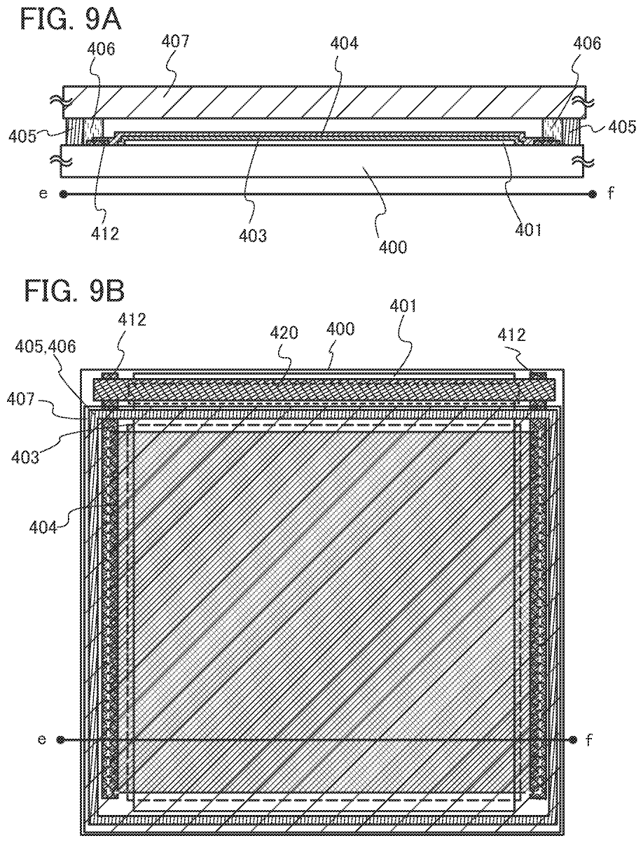

In this embodiment, an example in which the light-emitting device described in any one of Embodiments 1 to 6 is used for a lighting device will be described with reference to FIGS. 9A and 9B. FIG. 9B is a top view of the lighting device, and FIG. 9A is a cross-sectional view taken along the line e-f in FIG. 9B.

In the lighting device in this embodiment, a first electrode 401 is formed over a substrate 400 which is a support and has a light-transmitting property. The first electrode 401 corresponds to the electrode 101 in any one of Embodiments 1 to 6. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The EL layer 403 corresponds to the structure of the layer 104, the unit 103, and the layer 105, the structure of the layer 104, the unit 103, the intermediate layer 106, the unit 103(2), and the layer 105, or the like in any one of Embodiments 1 to 6. Refer to the corresponding description for these structures.

The second electrode 404 is formed to cover the EL layer 403. The second electrode 404 corresponds to the electrode 102 in any one of Embodiments 1 to 6. The second electrode 404 is formed using a material having high reflectance when light is extracted from the first electrode 401 side. The second electrode 404 is connected to the pad 412, whereby voltage is applied.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 provided with the light-emitting device having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 9B) can be mixed with a desiccant that enables moisture to be adsorbed, which results in improved reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

The lighting device described in this embodiment includes, as an EL element, the light-emitting device described in any one of Embodiments 1 to 6, and thus can be a lighting device with low power consumption.

### Embodiment 10

In this embodiment, examples of electronic devices each including the light-emitting device described in any one of Embodiments 1 to 6 will be described. The light-emitting device described in any one of Embodiments 1 to 6 has high emission efficiency and low power consumption. As a result, the electronic devices described in this embodiment can each include a light-emitting portion having low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

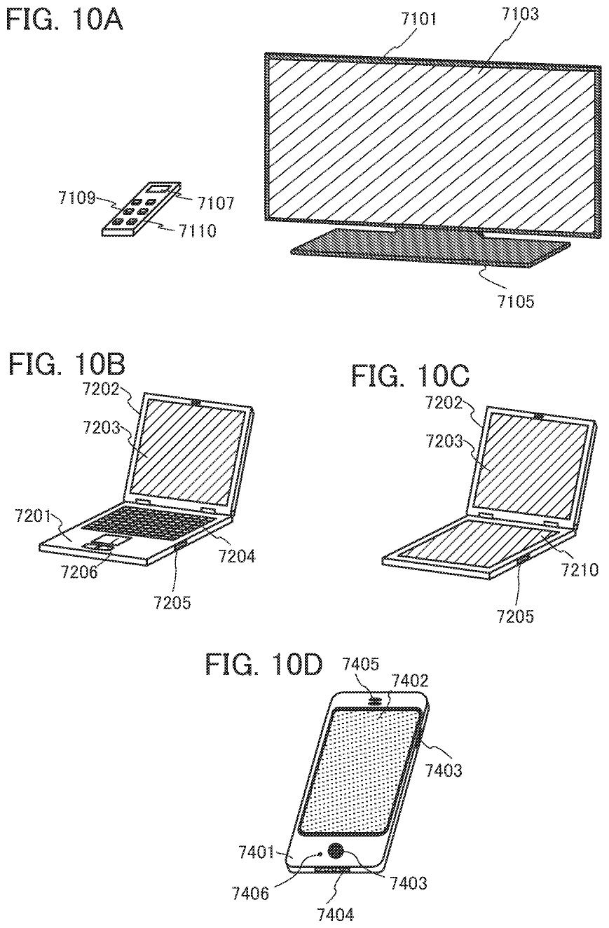

FIG. 10A shows an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in any one of Embodiments 1 to 6 are arranged in a matrix.

The television device can be operated with an operation switch of the housing 7101 or a separate remote controller 7110. With operation keys 7109 of the remote controller 7110, channels or volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, or the like. With use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 10B illustrates a computer, which includes a main body 7201, a housing 7202, a display portion 7203, a keyboard 7204, an external connection port 7205, a pointing device 7206, and the like. Note that this computer is fabricated using the light-emitting devices described in any one of Embodiments 1 to 6 and arranged in a matrix in the display portion 7203. The computer illustrated in FIG. 10B may have a structure illustrated in FIG. 10C. A computer illustrated in FIG. 10C is provided with a second display portion 7210 instead of the keyboard 7204 and the pointing device 7206. The second display portion 7210 is a touch panel, and input operation can be performed by touching display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 10D shows an example of a portable terminal. The portable terminal is provided with a display portion 7402 incorporated in a housing 7401, operation buttons 7403, an external connection port 7404, a speaker 7405, a microphone 7406, and the like. Note that the portable terminal has the display portion 7402 including the light-emitting devices described in any one of Embodiments 1 to 6 and arranged in a matrix.

When the display portion 7402 of the portable terminal illustrated in FIG. 10D is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source which emits near-infrared light in the display portion, an image of a finger vein, a palm vein, or the like can be taken.

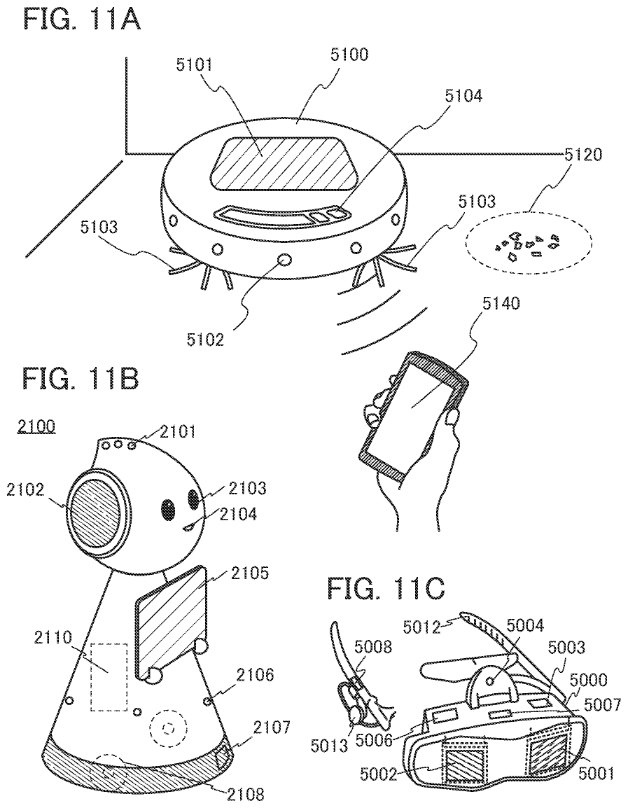

FIG. 11A is a schematic view showing an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103 (e.g., a wire) by image analysis, the rotation of the brush 5103 can be stopped.

The display 5101 can display the remaining capacity of a battery, the amount of collected dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 11B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 11C shows an example of a goggle-type display. The goggle-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 5008, a display portion 5002, a support 5012, and an earphone 5013.

The light-emitting apparatus of one embodiment of the present invention can be used for the display portion 5001 and the display portion 5002.

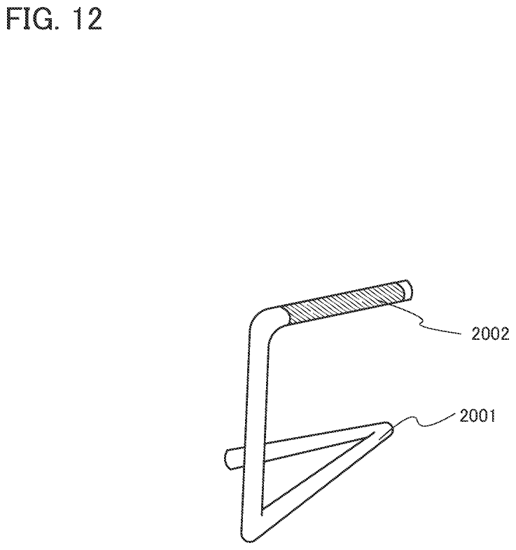

FIG. 12 shows an example in which the light-emitting device described in any one of Embodiments 1 to 6 is used for a table lamp which is a lighting device. The table lamp illustrated in FIG. 12 includes a housing 2001 and a light source 2002, and the lighting device described in Embodiment 9 may be used for the light source 2002.

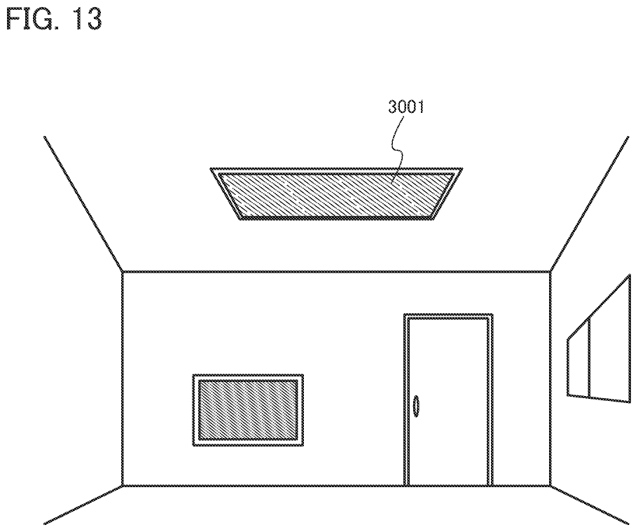

FIG. 13 shows an example in which the light-emitting device described in any one of Embodiments 1 to 6 is used for an indoor lighting device 3001. Since the light-emitting device described in any one of Embodiments 1 to 6 has high emission efficiency, the lighting device can have low power consumption. Furthermore, since the light-emitting device described in any one of Embodiments 1 to 6 can have a large area, the light-emitting device can be used for a large-area lighting device. Furthermore, since the light-emitting device described in any one of Embodiments 1 to 6 is thin, the light-emitting device can be used for a thin lighting device having.

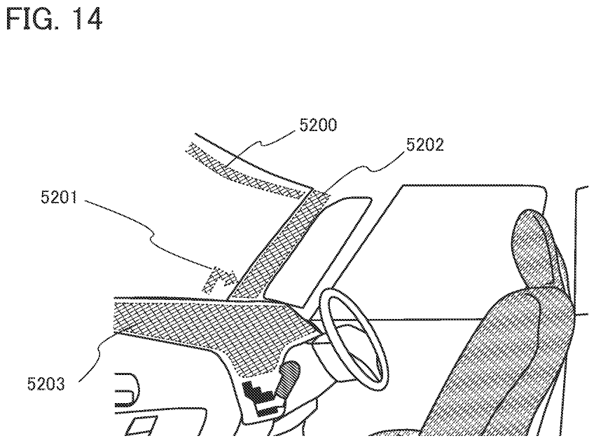

The light-emitting device described in any one of Embodiments 1 to 6 can also be used for an automobile windshield or an automobile dashboard. FIG. 14 illustrates one mode in which the light-emitting device described in any one of Embodiments 1 to 6 is used for an automobile windshield or an automobile dashboard. Display regions 5200 to 5203 each include the light-emitting device described in any one of Embodiments 1 to 6.

The display regions 5200 and 5201 are display devices which are provided in the automobile windshield and in which the light-emitting device described in any one of Embodiments 1 to 6 is incorporated. The light-emitting device described in any one of Embodiments 1 to 6 can be formed into what is called a see-through display device, through which the opposite side can be seen, by including a first electrode and a second electrode having a light-transmitting property. Such see-through display devices can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

A display device incorporating the light-emitting device described in any one of Embodiments 1 to 6 is provided in the display region 5202 in a pillar portion. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile. Thus, blind areas can be eliminated to enhance the safety. Images that compensate for the areas which a driver cannot see enable the driver to ensure safety easily and comfortably.

The display region 5203 can provide a variety of kinds of information by displaying navigation data, speed, a tachometer, a mileage, a fuel level, a gearshift state, air-condition setting, and the like. The content or layout of the display can be changed freely by a user as appropriate. Note that such information can also be displayed on the display regions 5200 to 5202. The display regions 5200 to 5203 can also be used as lighting devices.

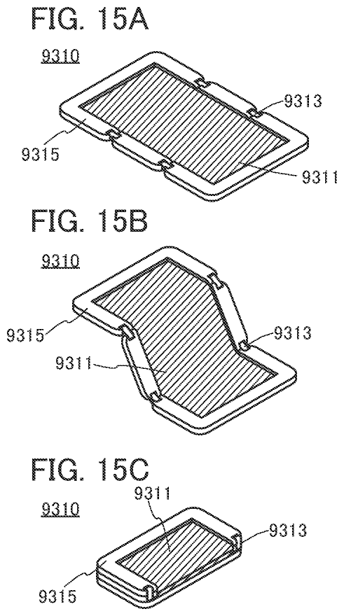

FIGS. 15A to 15C illustrate a foldable portable information terminal 9310. FIG. 15A illustrates the portable information terminal 9310 that is opened. FIG. 15B illustrates the portable information terminal 9310 in the middle of change from one of an opened state and a folded state to the other. FIG. 15C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structure described in this embodiment can be combined with any of the structures described in Embodiments 1 to 6 as appropriate.

As described above, the application range of the light-emitting apparatus including the light-emitting device described in any one of Embodiments 1 to 6 is wide, and thus the light-emitting apparatus can be applied to electronic devices in a variety of fields. By using the light-emitting device described in any one of Embodiments 1 to 6, an electronic device with low power consumption can be obtained.

Note that this embodiment can be combined with any of the other embodiments in this specification as appropriate.

### Example 1

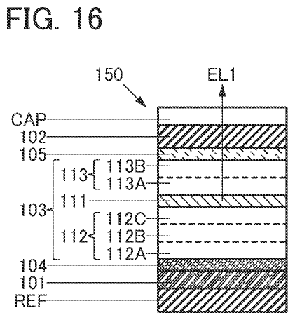

In this example, structures of a light-emitting device 1 and a light-emitting device 2 of one embodiment of the present invention are described with reference to FIG. 16 to FIG. 24.

FIG. 16 illustrates a structure of a light-emitting device.

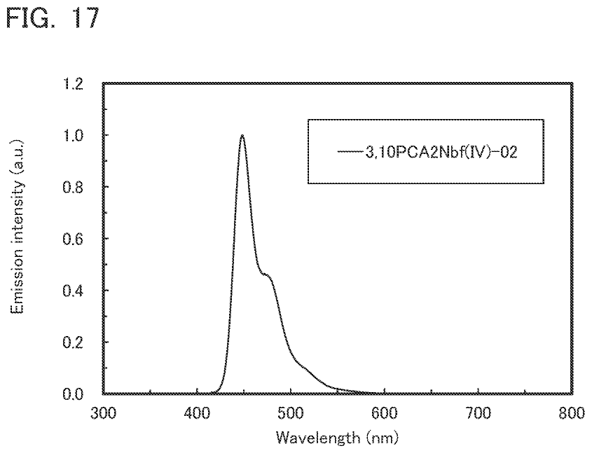

FIG. 17 is a graph showing an emission spectrum of a light-emitting material of an example.

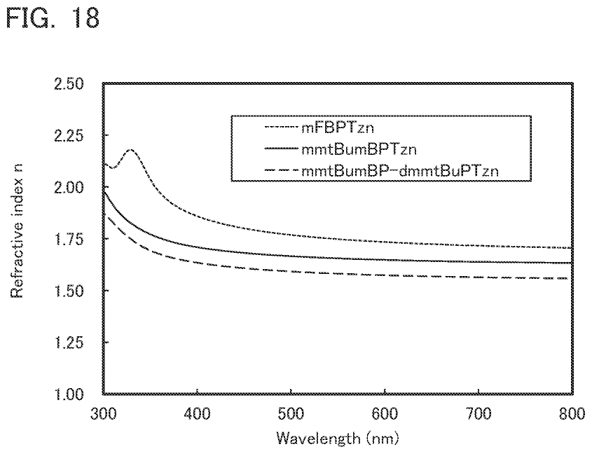

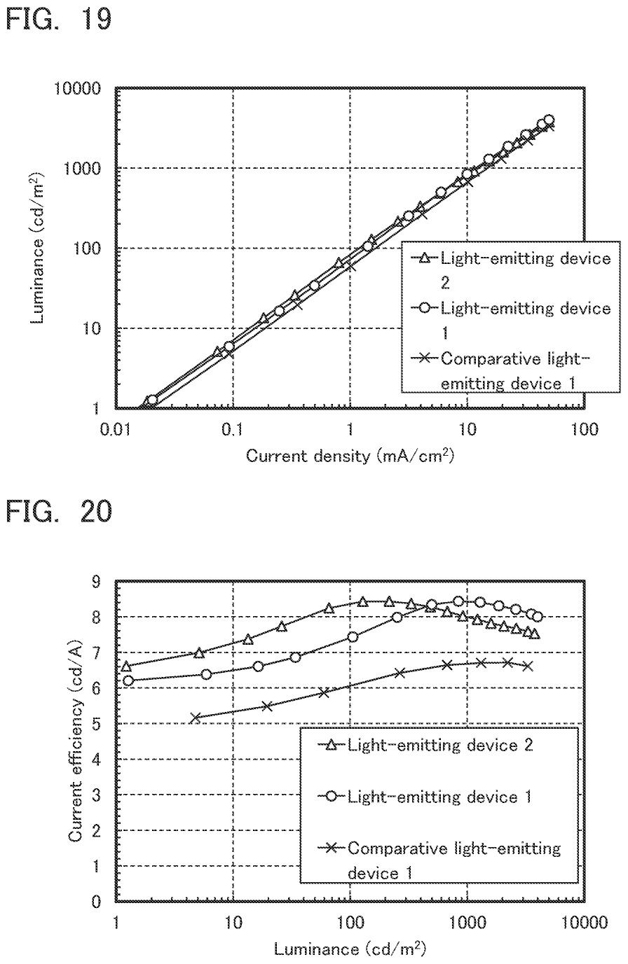

FIG. 18 is a graph showing wavelength-refractive index characteristics of organic compounds ETM of examples.

FIG. 19 is a graph showing current density-luminance characteristics of light-emitting devices.

FIG. 20 is a graph showing luminance-current efficiency characteristics of light-emitting devices.

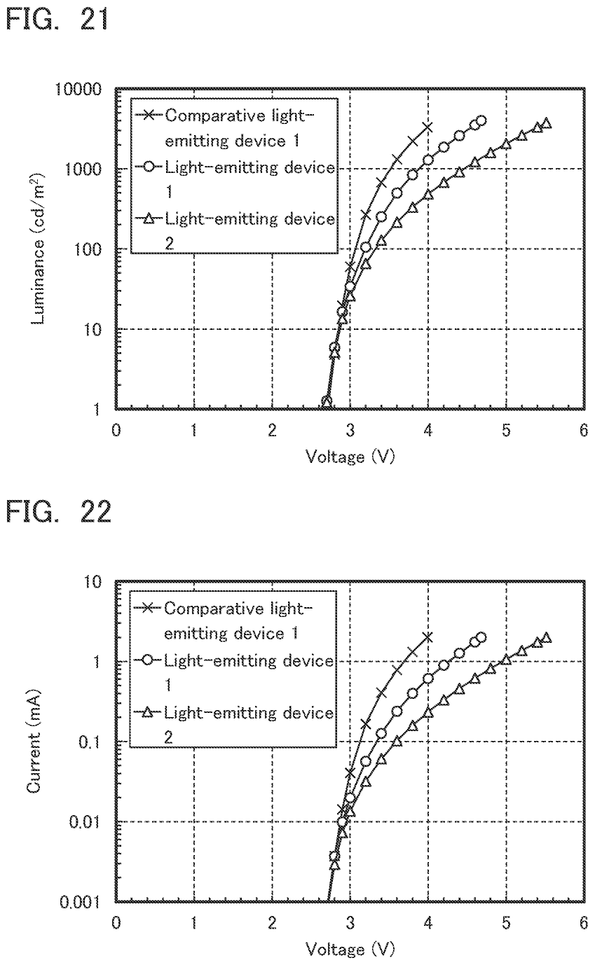

FIG. 21 is a graph showing voltage-luminance characteristics of light-emitting devices.

FIG. 22 is a graph showing voltage-current characteristics of light-emitting devices.

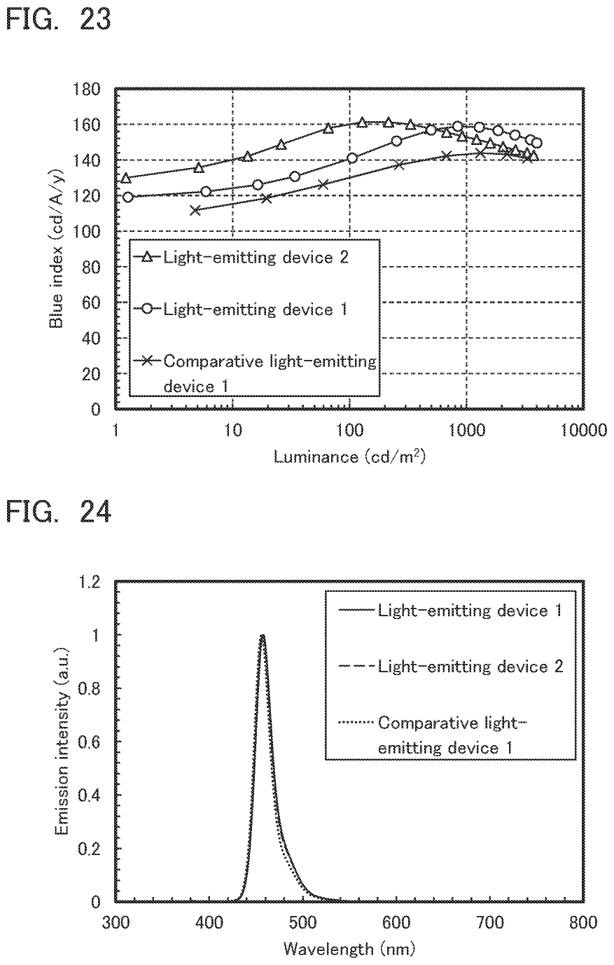

FIG. 23 is a graph showing luminance-blue index characteristics of light-emitting devices. Note that the blue index (BI) is a value obtained by dividing current efficiency (cd/A) by chromaticity y, and is one of the indicators of characteristics of blue light emission. As the chromaticity y is smaller, the color purity of blue light emission tends to be higher. With high color purity, a wide range of blue can be expressed even with a small number of luminance components; thus, using blue light emission with high color purity reduces the luminance needed for expressing blue, leading to lower power consumption. Thus, BI that is based on chromaticity y, which is one of the indicators of color purity of blue, is suitably used as a means for showing efficiency of blue light emission. The light-emitting device with higher BI can be regarded as a blue light-emitting device having higher efficiency for a display.

FIG. 24 is a graph showing emission spectra of light-emitting devices emitting light at a luminance of 1000 cd/m².

### <Light-Emitting Device 1>

The fabricated light-emitting device 1, which is described in this example, has a structure similar to that of the light-emitting device 150 (see FIG. 16).

The light-emitting device 150 includes the electrode 101, the electrode 102, and the unit 103. The electrode 102 includes the region overlapping with the electrode 101, and the unit 103 includes the region sandwiched between the electrode 101 and the electrode 102. The unit 103 includes the layer 111, the layer 112, and the layer 113. Furthermore, the light-emitting device 150 includes the layer 104 and the layer 105.

The layer 111 includes the region sandwiched between the electrode 101 and the electrode 102, and the layer 111 includes a light-emitting material. The light-emitting material emits photoluminescent light, and the photoluminescent light has a first spectrum ϕ1. The first spectrum ϕ1 has a maximum peak at the wavelength λ1, and the wavelength λ1 is in the range greater than or equal to 440 nm and less than or equal to 470 nm. Specifically, 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) was used as the light-emitting material. FIG. 17 shows an emission spectrum of 3,10PCA2Nbf(IV)-02. The emission spectrum of 3,10PCA2Nbf(IV)-02 in a toluene solution has a maximum peak at 448 nm, which is in the range greater than or equal to 440 nm and less than or equal to 470 nm. In addition, the full width at half maximum FWHM is 26 nm, which is in the range greater than or equal to 10 nm and less than or equal to 35 nm. Note that the photoluminescence spectrum of the light-emitting material was measured at room temperature with a fluorescence spectrophotometer (FP-8600, manufactured by JASCO Corporation).

The layer 112 includes the region sandwiched between the electrode 101 and the layer 111.

The layer 113 includes the region sandwiched between the layer 111 and the electrode 102, the layer 113 includes the organic compound ETM, the organic compound ETM has the first refractive index n1 with respect to light having the wavelength λ1, and the first refractive index n1 is more than or equal to 1.4 and less than or equal to 1.75. Specifically, 2-{(3′,5′-di-tert-butyl)-1,1′-biphenyl-3-yl}-4,6-diphenyl-1,3,5-triazine (abbreviation: mmtBumBPTzn) was used as the organic compound ETM. FIG. 18 shows wavelength-refractive index characteristics of mmtBumBPTzn. Note that in FIG. 18, the refractive indices of ordinary rays n, Ordinary are shown. In the wavelength range greater than or equal to 440 nm and less than or equal to 470 nm, the refractive index of mmtBumBPTzn is in the range from 1.67 to 1.68, which is more than or equal to 1.4 and less than or equal to 1.75. Note that the samples were fabricated by depositing materials for the respective layers to a thickness of approximately 50 nm over a quartz substrate by a vacuum evaporation method. Then, the refractive indices of the samples were measured with a spectroscopic ellipsometer (M-2000U, produced by J.A. Woollam Japan Corp.). The refractive indices of ordinary rays n, Ordinary are shown.

Furthermore, the light-emitting device 1 includes the layer 104 and the layer 105. The layer 104 includes a region sandwiched between the unit 103 and the electrode 101, and the layer 105 includes a region sandwiched between the electrode 102 and the unit 103.

### «Structure of Light-Emitting Device 1»

Table 1 shows the structure of the light-emitting device 1. Structural formulae of materials used in the light-emitting devices described in this example are shown below.

TABLE 1

| | Reference | | Composition | Thick- |
|---|---|---|---|---|
| Component | numeral | Material | ratio | ness/nm |
| Layer | CAP | DBT3PII | | 70 |
| Electrode | 102 | Ag:Mg | 10:1 | 15 |
| Layer | 105 | Liq | | 1 |
| Layer | 113B | mmtBumBPTzn:Liq | 0.5:0.5 | 20 |
| Layer | 113A | mmtBumBPTzn | | 10 |
| Layer | 111 | Bnf(II)PhA:3, | 1:0.015 | 25 |
| | | 10PCA2Nbf(IV)-02 | | |
| Layer | 112C | PCzN2 | | 10 |
| Layer | 112B | DBfBB1TP | | 10 |
| Layer | 112A | PCBBiF | | 20 |
| Layer | 104 | PCBBiF:OCHD-003 | 1:0.05 | 10 |
| Electrode | 101 | ITSO | | 85 |
| Reflective | REF | APC | | 100 |
| film | | | | |

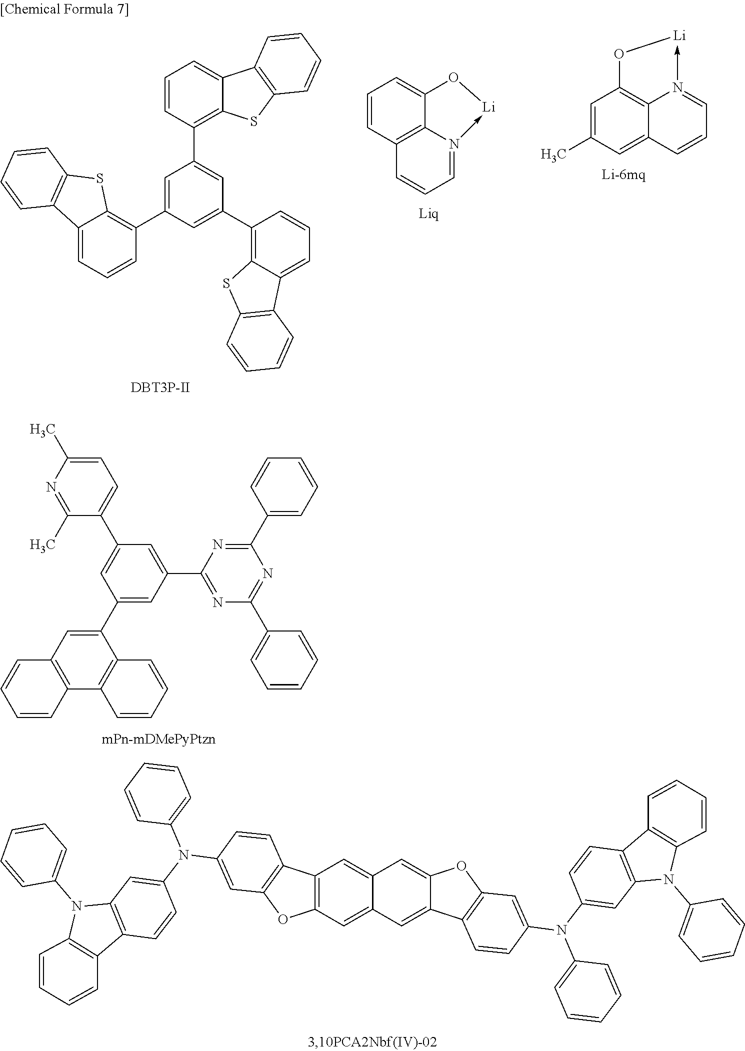

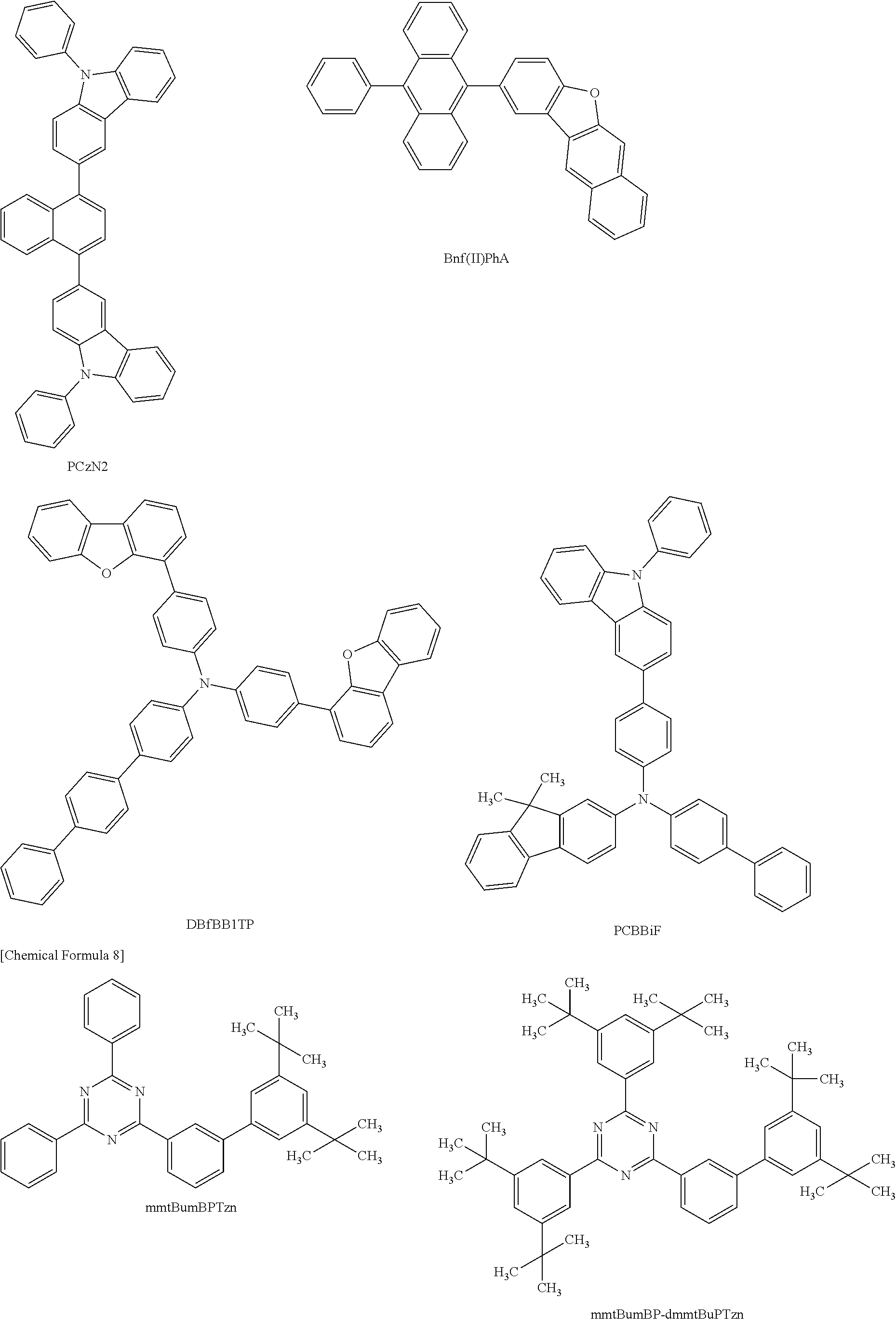

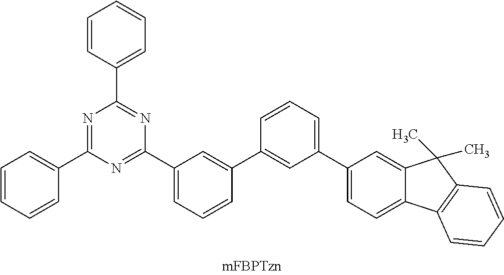 [SMILES: CC1(C)c2ccccc2-c2ccc(-c3cccc(-c4cccc(-c5nc(-c6ccccc6)nc(-c6ccccc6)n5)c4)c3)cc21]

### «Method for Fabricating Light-Emitting Device 1»

The light-emitting device 1 described in this example was fabricated using a method including the following steps.

### [First Step]

In the first step, a reflective film REF was formed, specifically by a sputtering method using an alloy of silver, palladium, and copper (abbreviation: APC) as a target.

The reflective film REF includes APC and has a thickness of 100 nm.

### [Second Step]

In the second step, the electrode 101 was formed over the reflective film REF, specifically by a sputtering method using indium oxide-tin oxide containing silicon or silicon oxide (abbreviation: ITSO) as a target.

The electrode 101 includes ITSO and has a thickness of 85 nm and an area of 4 mm² (2 mm×2 mm).

Next, a substrate over which the electrode 101 was formed was washed with water, baked at 200° C. for an hour, and then subjected to UV ozone treatment for 370 seconds. Then, the substrate was transferred into a vacuum evaporation apparatus where the pressure was reduced to approximately 10-4 Pa, and vacuum baking was performed at 170° C. for 30 minutes in a heating chamber of the vacuum evaporation apparatus. Then, the substrate was cooled down for approximately 30 minutes.

### [Third Step]

In the third step, the layer 104 was formed over the electrode 101. Specifically, materials of the layer 104 were co-deposited by a resistance-heating method.

The layer 104 includes N-(1,1′-biphenyl-4-yl)-N-[4-(9-phenyl-9H-carbazol-3-yl)phenyl]-9,9-dimethyl-9H-fluoren-2-amine (abbreviation: PCBBiF) and an electron acceptor material (abbreviation: OCHD-003) at PCBBiF:OCHD-003=1:0.05 in a weight ratio and has a thickness of 10 nm. Note that OCHD-003 contains fluorine, has an acceptor property, and has a molecular weight of 672.

### [Fourth Step]

In the fourth step, a layer 112A was formed over the layer 104. Specifically, a material of the layer 112A was deposited by a resistance-heating method.

The layer 112A includes PCBBiF and has a thickness of 20 nm.

### [Fifth Step]

In the fifth step, a layer 112B was formed over the layer 112A. Specifically, a material of the layer 112B was deposited by a resistance-heating method.

The layer 112B includes N,N-bis[4-(dibenzofuran-4-yl)phenyl]-4-amino-p-terphenyl (abbreviation: DBfBBITP) and has a thickness of 10 nm.

### [Sixth Step]

In the sixth step, a layer 112C was formed over the layer 112B. Specifically, a material of the layer 112C was deposited by a resistance-heating method.

The layer 112C includes 3,3′-(naphthalene-1,4-diyl)bis(9-phenyl-9H-carbazole) (abbreviation: PCzN2) and has a thickness of 10 nm.

### [Seventh Step]

In the seventh step, the layer 111 was formed over the layer 112C. Specifically, materials of the layer 111 were co-deposited by a resistance-heating method.

The layer 111 includes 2-(10-phenyl-9-anthracenyl)-benzo[b]naphtho[2,3-d]furan (abbreviation: Bnf(II)PhA) and 3,10PCA2Nbf(IV)-02 at Bnf(II)PhA:3,10PCA2Nbf(IV)-02=1:0.015 in a weight ratio and has a thickness of 25 nm.

### [Eighth Step]

In the eighth step, a layer 113A was formed over the layer 111. Specifically, a material of the layer 113A was deposited by a resistance-heating method.

The layer 113A includes mmtBumBPTzn and has a thickness of 10 nm.

### [Ninth Step]

In the ninth step, a layer 113B was formed over the layer 113A. Specifically, materials of the layer 113B were co-deposited by a resistance-heating method.

The layer 113B includes mmtBumBPTzn and 8-hydroxyquinolinato-lithium (abbreviation: Liq) at mmtBumBPTzn:Liq=0.5:0.5 in a weight ratio and has a thickness of 20 nm.

### [Tenth Step]

In the tenth step, the layer 105 was formed over the layer 113B. Specifically, a material of the layer 105 was deposited by a resistance-heating method.

The layer 105 includes Liq and has a thickness of 1 nm.

### [Eleventh Step]

In the eleventh step, the electrode 102 was formed over the layer 105. Specifically, materials of the electrode 102 were co-deposited by a resistance-heating method.

The electrode 102 includes Ag and Mg at Ag:Mg=10:1 in a volume ratio and has a thickness of 15 nm.

### [Twelfth Step]

In the twelfth step, a layer CAP was formed over the electrode 102. Specifically, a material of the layer CAP was deposited by a resistance-heating method.

The layer CAP includes 1,3,5-tri(dibenzothiophen-4-yl)-benzene (abbreviation: DBT3PII) and has a thickness of 70 nm.

### «Operation Characteristics of Light-Emitting Device 1»

When supplied with electric power, the light-emitting device 1 emitted the light EL1 (see FIG. 16). Operation characteristics of the light-emitting device 1 were measured (see FIG. 19 to FIG. 24). Note that the measurement was performed at room temperature.

Table 2 shows main initial characteristics of the light-emitting device 1 emitting light at a luminance of approximately 1000 cd/m². Luminance, CIE chromaticity, and emission spectra were measured at normal temperature with a spectroradiometer (SR-UL1R manufactured by TOPCON TECHNOHOUSE CORPORATION). Note that initial characteristics of the other light-emitting devices are also noted in Table 2. The structures of the other light-emitting devices are described later.

TABLE 2

| | | | Current | Chroma- | Chroma- | Current | Blue |
|---|---|---|---|---|---|---|---|
| | Voltage | Current | density | ticity | ticity | efficiency | index |
| | (V) | (mA) | (mA/cm²) | x | y | (cd/A) | (cd/A/y) |
| Light-emitting | 3.8 | 0.40 | 10.0 | 0.14 | 0.05 | 8.4 | 158.9 |
| device 1 | | | | | | | |
| Light-emitting | 4.4 | 0.46 | 11.4 | 0.14 | 0.05 | 8.0 | 153.3 |
| device 2 | | | | | | | |
| Comparative | 3.6 | 0.78 | 19.6 | 0.14 | 0.05 | 6.7 | 143.8 |
| light-emitting | | | | | | | |
| device 1 | | | | | | | |

Note that the blue index (BI) is a value obtained by dividing current efficiency (cd/A) by chromaticity y, and is one of the indicators of characteristics of blue light emission. As the chromaticity y is smaller, the color purity of blue light emission tends to be higher. With high color purity, a wide range of blue can be expressed even with a small number of luminance components; thus, using blue light emission with high color purity reduces the luminance needed for expressing blue, leading to lower power consumption. Thus, BI that is based on chromaticity y, which is one of the indicators of color purity of blue, is suitably used as a means for showing efficiency of blue light emission. The light-emitting device with higher BI can be regarded as a blue light-emitting device having higher efficiency for a display.

### <Light-Emitting Device 2>

The fabricated light-emitting device 2, which is described in this example, is different from the light-emitting device 1 in the structures of the layer 113A, the layer 113B, and the layer 105.

### «Structure of Light-Emitting Device 2»

Table 3 shows the structure of the light-emitting device 2. Note that 2-{(3′,5′-di-tert-butyl)-1,1′-biphenyl-3-yl}-4,6-bis(3,5-di-tert-butylphenyl)-1,3,5-triazine (abbreviation: mmtBumBP-dmmtBuPTzn) was used as the organic compound ETM. FIG. 18 shows wavelength-refractive index characteristics of mmtBumBP-dmmtBuPTzn. In the wavelength range greater than or equal to 440 nm and less than or equal to 470 nm, the refractive index of mmtBumBP-dmmtBuPTzn is in the range from 1.60 to 1.61, which is more than or equal to 1.4 and less than or equal to 1.75.

TABLE 3

| | Reference | | Composition | Thick- |
|---|---|---|---|---|
| Component | numeral | Material | ratio | ness/nm |
| Layer | CAP | DBT3PII | | 70 |
| Electrode | 102 | Ag:Mg | 10:1 | 15 |
| Layer | 105 | Li-6mq | | 1 |
| Layer | 113B | mmtBumBP-dmmtBuPTzn:Li-6mq | 0.5:0.5 | 20 |
| Layer | 113A | mmtBumBP-dmmtBuPTzn | | 10 |
| Layer | 111 | Bnf(II)PhA:3, 10PCA2Nbf(IV)-02 | 1:0.015 | 25 |
| Layer | 112C | PCzN2 | | 10 |
| Layer | 112B | DBfBB1TP | | 10 |
| Layer | 112A | PCBBiF | | 20 |
| Layer | 104 | PCBBiF:OCHD-003 | 1:0.05 | 10 |
| Electrode | 101 | ITSO | | 85 |
| Reflective film | REF | APC | | 100 |

### «Method for Fabricating Light-Emitting Device 2»

The light-emitting device 2 described in this example was fabricated using a method including the following steps.

The method for fabricating the light-emitting device 2 is different from the method for fabricating the light-emitting device 1 in the steps for forming the layer 113A, the layer 113B, and the layer 105. Here, different portions are described in detail, and the above description is referred to for the portions formed by a similar method.

### [Eighth Step]

In the eighth step, the layer 113A was formed over the layer 111. Specifically, a material of the layer 113A was deposited by a resistance-heating method.

The layer 113A includes mmtBumBP-dmmtBuPTzn and has a thickness of 10 nm.

### [Ninth Step]

In the ninth step, the layer 113B was formed over the layer 113A. Specifically, materials of the layer 113B were co-deposited by a resistance-heating method.

The layer 113B includes mmtBumBP-dmmtBuPTzn and 6-methyl-8-quinolinolato-lithium (abbreviation: Li-6mq) at mmtBumBP-dmmtBuPTzn:Li-6mq=0.5:0.5 in a weight ratio and has a thickness of 20 nm.

### [Tenth Step]

In the tenth step, the layer 105 was formed over the layer 113B. Specifically, a material of the layer 105 was deposited by a resistance-heating method.

The layer 105 includes Li-6mq and has a thickness of 1 nm.

### «Operation Characteristics of Light-Emitting Device 2»

When supplied with electric power, the light-emitting device 2 emitted the light EL1 (see FIG. 16). Operation characteristics of the light-emitting device 2 were measured (see FIG. 19 to FIG. 24). Note that the measurement was performed at room temperature.

Table 2 shows main initial characteristics of the light-emitting device 2 emitting light at a luminance of approximately 1000 cd/m².

The light-emitting device 1 and the light-emitting device 2, which are embodiments of the present invention, showed higher current efficiencies and higher blue indices than a comparative light-emitting device 1, which is described later. Thus, one embodiment of the present invention is suitable for a light-emitting device used for a display.

### Reference Example 1

Table 4 shows the structure of the comparative light-emitting device 1. Note that 2-[3′-(9,9-dimethyl-9H-fluoren-2-yl)biphenyl-3-yl]-4,6-diphenyl-1,3,5-triazine (abbreviation: mFBPTzn) was used as an electron-transport material. FIG. 18 shows wavelength-refractive index characteristics of mFBPTzn. In the wavelength range greater than or equal to 440 nm and less than or equal to 470 nm, the refractive index of mFBPTzn is in the range from 1.79 to 1.81.

The fabricated comparative light-emitting device 1, which is described in this example, is different from the light-emitting device 1 in the thickness of the layer 112A and the structures of the layer 113A and the layer 113B. In the comparative light-emitting device 1, the layer 113A includes 2-[3′-(9,9-dimethyl-9H-fluoren-2-yl)biphenyl-3-yl]-4,6-diphenyl-1,3,5-triazine (abbreviation: mFBPTzn), and the layer 113B includes 2-[3-(2,6-dimethyl-3-pyridinyl)-5-(9-phenanthrenyl)phenyl]-4,6-diphenyl-1,3,5-triazine (abbreviation: mPn-mDMePyPTm).

TABLE 4

| | | | Com- | Thick- |
|---|---|---|---|---|
| | Reference | | position | ness/ |
| Component | numeral | Material | ratio | nm |
| Layer | CAP | DBT3PII | | 70 |
| Electrode | 102 | Ag:Mg | 10:1 | 15 |
| Layer | 105 | Liq | | 1 |
| Layer | 113B | mPn-mDMePyPTzn:Liq | 1:1 | 20 |
| Layer | 113A | mFBPTzn | | 10 |
| Layer | 111 | Bnf(II)PhA:3, | 1:0.015 | 25 |
| | | 10PCA2Nbf(IV)-02 | | |
| Layer | 112C | PCzN2 | | 10 |
| Layer | 112B | DBfBB1TP | | 10 |
| Layer | 112A | PCBiF | | 15 |
| Layer | 104 | PCBiF:OCHD-003 | 1:0.05 | 10 |
| Electrode | 101 | ITSO | | 85 |
| Reflective | REF | APC | | 100 |
| film | | | | |

### «Method for Fabricating Comparative Light-Emitting Device 1»

The comparative light-emitting device 1 was fabricated using a method including the following steps.

The method for fabricating the comparative light-emitting device 1 is different from the method for fabricating the light-emitting device 1 in the steps for forming the layer 112A, the layer 113A, and the layer 113B. Here, different portions are described in detail, and the above description is referred to for the portions formed by a similar method.

### [Fourth Step]

In the fourth step, the layer 112A was formed over the layer 104. Specifically, a material of the layer 112A was deposited by a resistance-heating method.

The layer 112A includes PCBBiF and has a thickness of 15 nm.

### [Eighth Step]

In the eighth step, the layer 113A was formed over the layer 111. Specifically, a material of the layer 113A was deposited by a resistance-heating method.

The layer 113A includes mFBPTzn and has a thickness of 10 nm.

### [Ninth Step]

In the ninth step, the layer 113B was formed over the layer 113A. Specifically, materials of the layer 113B were co-deposited by a resistance-heating method.

The layer 113B includes mPn-mDMePyPTzn and Liq at mPn-mDMePyPTzn:Liq=1:1 in a weight ratio and has a thickness of 20 nm.

### «Operation Characteristics of Comparative Light-Emitting Device 1»

When supplied with electric power, the comparative light-emitting device 1 emitted the light EL1 (see FIG. 16). Operation characteristics of the comparative light-emitting device 1 were measured (see FIG. 19 to FIG. 24). Note that the measurement was performed at room temperature.

Table 2 shows main initial characteristics of the comparative light-emitting device 1 emitting light at a luminance of approximately 1000 cd/m².

### Example 2

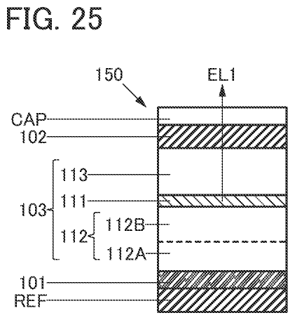

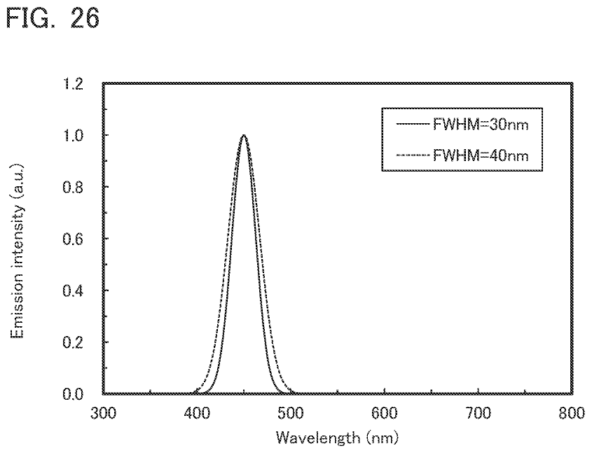

In this example, a structure of a light-emitting device 3 of one embodiment of the present invention is described with reference to FIG. 25 and FIG. 26.

FIG. 25 illustrates the structure of the light-emitting device.

FIG. 26 is a graph showing emission spectra of light-emitting materials of this example.

### <Light-Emitting Device 3>

The fabricated light-emitting device 3, which is described in this example, has a structure similar to that of the light-emitting device 150 (see FIG. 25).

The light-emitting device 150 includes the electrode 101, the electrode 102, and the unit 103. The electrode 102 includes the region overlapping with the electrode 101, and the unit 103 includes the region sandwiched between the electrode 101 and the electrode 102. The unit 103 includes the layer 111, the layer 112, and the layer 113.

The layer 111 includes the region sandwiched between the electrode 101 and the electrode 102, and the layer 111 includes a light-emitting material. The light-emitting material emits photoluminescent light, and the photoluminescent light has a spectrum. The spectrum has a maximum peak at the wavelength λ1, and the wavelength λ1 is in the range greater than or equal to 440 nm and less than or equal to 470 nm. Specifically, the emission spectrum of the light-emitting material in a solution has a maximum peak at 450 nm and a full width at half maximum FWHM of 30 nm (see FIG. 26). Note that the full width at half maximum FWHM is in the range greater than or equal to 10 nm and less than or equal to 35 nm.

The layer 112 includes the region sandwiched between the electrode 101 and the layer 111.

The layer 113 includes the region sandwiched between the layer 111 and the electrode 102, the layer 113 includes the organic compound ETM, the organic compound ETM has the first refractive index n1 with respect to light having the wavelength λ1, and the first refractive index n1 is more than or equal to 1.4 and less than or equal to 1.75. Specifically, mmtBumBPTzn was used as the organic compound ETM. FIG. 18 shows wavelength-refractive index characteristics of mmtBumBPTzn. In the wavelength range greater than or equal to 440 nm and less than or equal to 470 nm, the refractive index of mmtBumBPTzn is in the range from 1.67 to 1.68, which is more than or equal to 1.4 and less than or equal to 1.75.

### «Structure of Light-Emitting Device 3»

Table 5 shows the structure of the light-emitting device 3. Structural formulae of materials used in the light-emitting device described in this example are shown above.

TABLE 5

| | Reference | | Composition | Thick- |
|---|---|---|---|---|
| Component | numeral | Material | ratio | ness/nm |
| Layer | CAP | DBT3PII | | 70 |
| Electrode | 102 | Ag:Mg | 10:1 | 15 |
| Layer | 113 | mmtBumBPTzn | | 30 |
| Layer | 111 | αN-βNPAnth | | 25 |
| Layer | 112B | DBfBB1TP | | 10 |
| Layer | 112A | PCBBiF | | 112 |
| Electrode | 101 | ITSO | | 10 |
| Reflective film | REF | APC | | 10 |

### «Simulation of Operation Characteristics of Light-Emitting Device 3»

Operation characteristics of the light-emitting device 3 were simulated. As software for the calculation, an organic device simulator (a semiconducting emissive thin film optics simulator: setfos, produced by Cybernet Systems Co., Ltd.) was used.

The result of the simulation was that the blue index of the light-emitting device 3 was 480.2 cd/A/y. Note that the blue index value of the light-emitting device 3 was 1.19 times that of a comparative light-emitting device 2 to be described later.

### Reference Example 2

The structure of the comparative light-emitting device 2 is different from that of the light-emitting device 3 in the structure of the layer 111. Specifically, the layer 111 of the comparative light-emitting device 2 includes a light-emitting material different from that of the layer 111 of the light-emitting device 3. The emission spectrum of the light-emitting material in a solution has a maximum peak at 450 nm and a full width at half maximum FWHM of 40 nm (see FIG. 26). The full width at half maximum FWHM is outside the range greater than or equal to 10 nm and less than or equal to 35 nm.

### «Simulation of Operation Characteristics of Comparative Light-Emitting Device 2»

Operation characteristics of the comparative light-emitting device 2 were simulated. The simulation was performed in a manner similar to that for the light-emitting device 3, with the result that the blue index of the comparative light-emitting device 2 was 404.3.

### Example 3

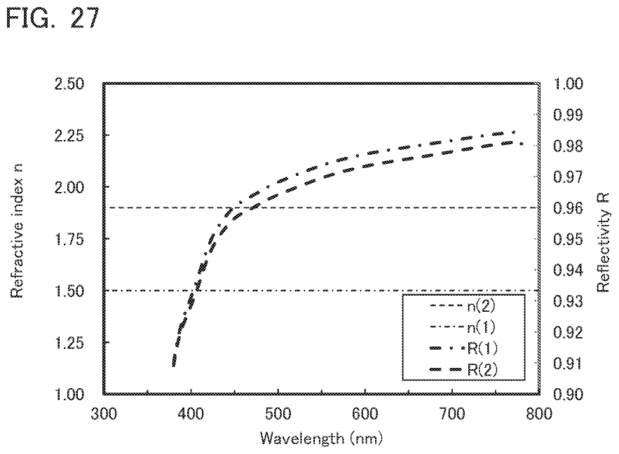

FIG. 27 is a graph showing wavelength-refractive index characteristics of the organic compound ETM of this example and wavelength-reflectivity characteristics of silver which the organic compound ETM is in contact with.

The reflectivity of silver which a layer having a refractive index of 1.5 is in contact with and the reflectivity of silver which a layer having a refractive index of 1.9 is in contact with were simulated using software. As the software for the calculation, an organic device simulator (a semiconducting emissive thin film optics simulator: setfos, produced by Cybernet Systems Co., Ltd.) was used.

The result of the calculation was that silver which a layer having a refractive index of 1.5 is in contact with has higher reflectivity than silver which a layer having a refractive index of 1.9 is in contact with (see FIG. 27).

### Reference Synthesis Example 1

An example of a synthesis method of the low-refractive-index electron-transport material, which was used as the organic compound ETM in an example, is described below.

First, a synthesis method of 2-{(3′,5′-di-tert-butyl)-1,1′-biphenyl-3-yl}-4,6-bis(3,5-di-tert-butylphenyl)-1,3,5-triazine (abbreviation: mmtBumBP-dmmtBuPTzn), which is an organic compound represented by Structural Formula (200), is described. The structure of mmtBumBP-dmmtBuPTzn is shown below.

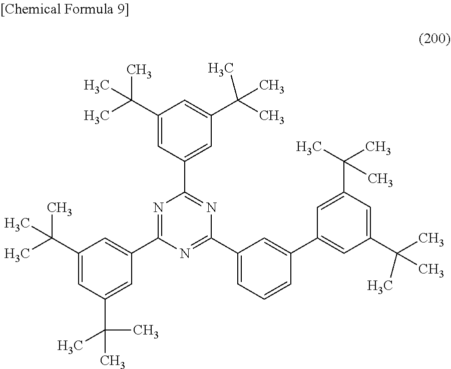 [SMILES: CC(C)(C)c1cc(-c2cccc(-c3nc(-c4cc(C(C)(C)C)cc(C(C)(C)C)c4)nc(-c4cc(C(C)(C)C)cc(C(C)(C)C)c4)n3)c2)cc(C(C)(C)C)c1]

### Step 1: Synthesis of 3-bromo-3′,5′-di-tert-butylbiphenyl

Into a three-neck flask were put 1.0 g (4.3 mmol) of 3,5-di-t-butylphenylboronic acid, 1.5 g (5.2 mmol) of 1-bromo-3-iodobenzene, 4.5 mL of an aqueous solution of potassium carbonate (2 mol/L), 20 mL of toluene, and 3 mL of ethanol, and the mixture was degassed by being stirred under reduced pressure. To this mixture were added 52 mg (0.17 mmol) of tris(2-methylphenyl)phosphine and 10 mg (0.043 mmol) of palladium(II) acetate, and reaction was caused under a nitrogen atmosphere at 80° C. for 14 hours. After the reaction, extraction was performed with toluene and the obtained organic layer was dried with magnesium sulfate. This mixture was subjected to gravity filtration, and the obtained filtrate was purified by silica gel column chromatography with a developing solvent of hexane to give 1.0 g of a target white solid in a yield of 68%. The synthesis scheme of Step 1 is shown below.

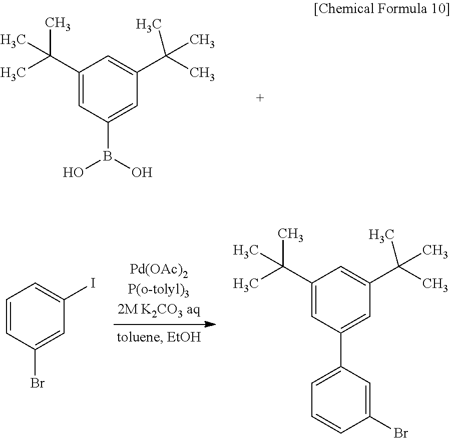 [SMILES: CC(C)(C)c1cc(B(O)O)cc(C(C)(C)C)c1 ; Brc1cccc(I)c1 ; CC(C)(C)c1cc(-c2cccc(Br)c2)cc(C(C)(C)C)c1]

### Step 2: 2-(3′,5′-di-tert-butylbiphenyl-3-yl)-4,4,5,5-tetramethyl-1,3,2-dioxaborolane

Into a three-neck flask were put 1.0 g (2.9 mmol) of 3-bromo-3′,5′-di-tert-butylbiphenyl, 0.96 g (3.8 mmol) of bis(pinacolato)diboron, 0.94 g (9.6 mmol) of potassium acetate, and 30 mL of 1,4-dioxane, and the mixture was degassed by being stirred under reduced pressure. To this mixture were added 0.12 g (0.30 mmol) of 2-dicyclohexylphosphino-2′,6′-dimethoxybiphenyl and 0.12 g (0.15 mmol) of [1,1′-bis(diphenylphosphino)ferrocene]palladium(II) dichloride dichloromethane adduct, and reaction was caused under a nitrogen atmosphere at 110° C. for 24 hours. After the reaction, extraction was performed with toluene and the obtained organic layer was dried with magnesium sulfate. This mixture was subjected to gravity filtration. The resulting filtrate was purified by silica gel column chromatography with a developing solvent of toluene to give 0.89 g of a target yellow oil in a yield of 78%. The synthesis scheme of Step 2 is shown below.

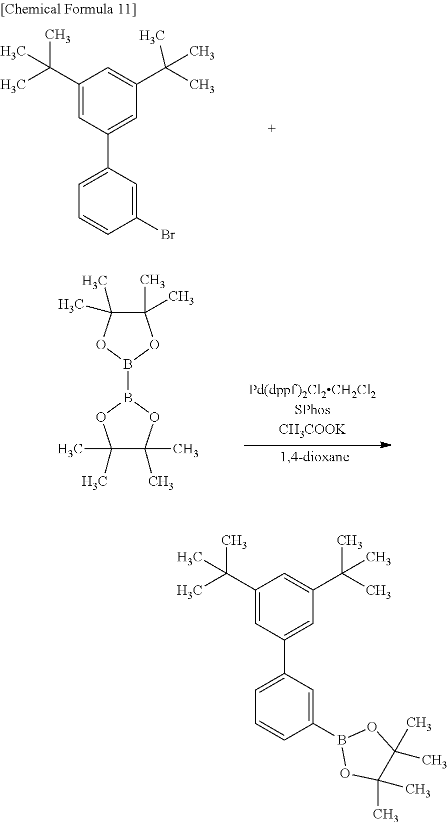

### Step 3: Synthesis of mmtBumBP-dmmtBuPTm

Into a three-neck flask were put 0.8 g (1.6 mmol) of 4,6-bis(3,5-di-tert-butyl-phenyl)-2-chloro-1,3,5-triazine, 0.89 g (2.3 mmol) of 2-(3′,5′-di-tert-butylbiphenyl-3-yl)-4,4,5,5-tetramethyl-1,3,2-dioxaborolane, 0.68 g (3.2 mmol) of tripotassium phosphate, 3 mL of water, 8 mL of toluene, and 3 mL of 1,4-dioxane, and the mixture was degassed by being stirred under reduced pressure. To this mixture were added 3.5 mg (0.016 mmol) of palladium(II) acetate and 10 mg (0.032 mmol) of tris(2-methylphenyl)phosphine, and the mixture was heated and refluxed under a nitrogen atmosphere for 12 hours. After the reaction, extraction was performed with ethyl acetate and the obtained organic layer was dried with magnesium sulfate. This mixture was subjected to gravity filtration. The resulting filtrate was concentrated, followed by purification by silica gel column chromatography with a developing solvent of ethyl acetate and hexane in a ratio of 1:20 to give a solid. This solid was purified by silica gel column chromatography with a developing solvent of chloroform and hexane in a ratio of 5:1, which was then changed to 1:0. The obtained solid was recrystallized with hexane to give 0.88 g of a target white solid in a yield of 76%. The synthesis scheme of Step 3 is shown below.

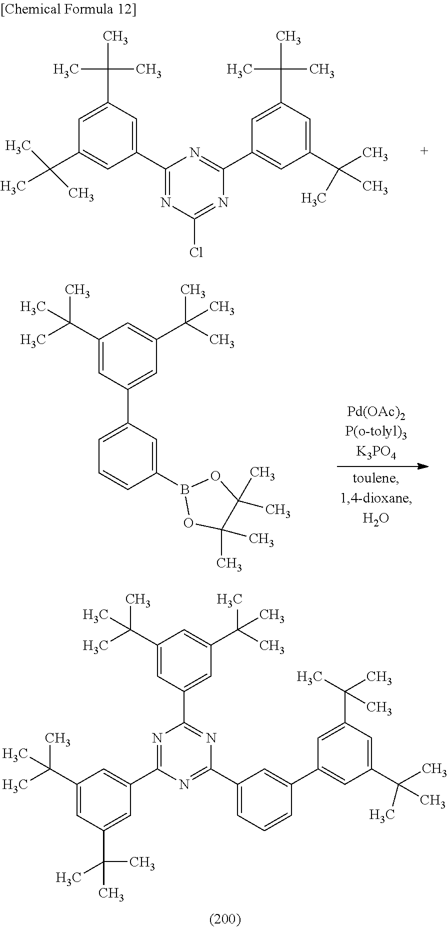

Then, 0.87 g of the obtained white solid was purified by a train sublimation method at 230° C. under a pressure of 5.8 Pa while an argon gas was made to flow. After the purification by sublimation, 0.82 g of a target white solid was obtained at a collection rate of 95%.

Analysis results by nuclear magnetic resonance spectroscopy (¹H-NMR) of the white solid obtained in Step 3 are shown below. The results show that mmtBumBP-dmmtBuPTzn represented by Structural Formula (200) shown above was obtained by the above synthesis method.

¹H NMR (CDCl₃, 300 MHz): δ=1.42-1.49 (m, 54H), 7.50 (s, 1H), 7.61-7.70 (m, 5H), 7.87 (d, 1H), 8.68-8.69 (m, 4H), 8.78 (d, 1H), 9.06 (s, 1H).

### Reference Synthesis Example 2

Similarly, 2-{(3′,5′-di-tert-butyl)-1,1′-biphenyl-3-yl}-4,6-diphenyl-1,3,5-triazine (abbreviation: mmtBumBPTzn), which is an organic compound represented by Structural Formula (201) below, was synthesized.

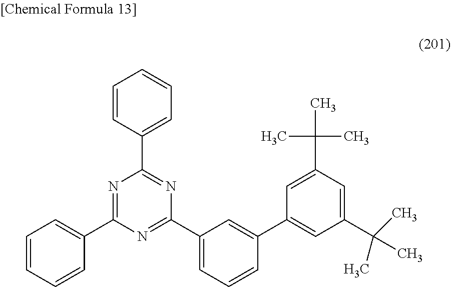 [SMILES: CC(C)(C)c1cc(-c2cccc(-c3nc(-c4ccccc4)nc(-c4ccccc4)n3)c2)cc(C(C)(C)C)c1]

Analysis results by nuclear magnetic resonance spectroscopy (¹H-NMR) of the above organic compound are shown below.

¹H NMR (CDCl₃, 300 MHz): δ=1.44 (s, 18H), 7.51-7.68 (m, 10H), 7.83 (d, 1H), 8.73-8.81 (m, 5H), 9.01 (s, 1H).

The organic compounds described above each have an ordinary refractive index of more than or equal to 1.50 and less than or equal to 1.75 in a blue light emission range (455 nm to 465 nm) or an ordinary refractive index of more than or equal to 1.45 and less than or equal to 1.70 with respect to light of wavelength 633 nm, which is usually used for measurement of refractive indices.

### Reference Synthesis Example 3

A synthesis method of 6-methyl-8-quinolinolato-lithium (abbreviation: Li-6mq), which was used in an example, is described. The structural formula of Li-6mq is shown below.

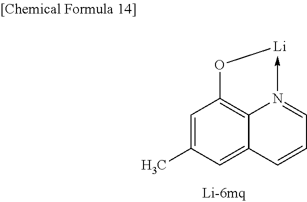

Into a three-neck flask were put 2.0 g (12.6 mmol) of 8-hydroxy-6-methylquinoline and 130 mL of dehydrated tetrahydrofuran (abbreviation: THF), and the mixture was stirred. To this solution was added 10.1 mL (10.1 mmol) of a 1M THF solution of lithium-tert-butoxide (abbreviation: tBuOLi), and the mixture was stirred at room temperature for 47 hours. The reaction solution was concentrated to give a yellow solid. Acetonitrile was added to this solid, and the mixture was irradiated with ultrasonic waves and then subjected to filtration to give a pale yellow solid. This washing operation was performed twice. As a residue, 1.6 g of a pale yellow solid of Li-6mq was obtained in a yield of 95%. The synthesis scheme is shown below.

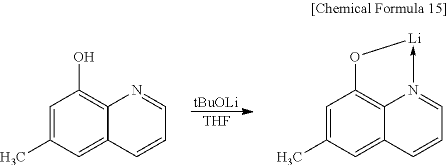

This application is based on Japanese Patent Application Serial No. 2020-184898 filed with Japan Patent Office on Nov. 5, 2020, the entire contents of which are hereby incorporated by reference.

What is claimed is:

1. A light-emitting device comprising:
a first electrode;
a second electrode;
a first layer; and
a second layer,
wherein the second electrode comprises a region overlapping with the first electrode,
wherein the first layer is between the first electrode and the second electrode,
wherein the first layer comprises a light-emitting material,
wherein the light-emitting material is configured to emit photoluminescent light in a solution,
wherein the photoluminescent light has a first spectrum ϕ1,
wherein the first spectrum ϕ1 has a maximum peak at a wavelength λ1,
wherein the wavelength λ1 is in a range greater than or equal to 440 nm and less than or equal to 470 nm,
wherein the second layer is between the first layer and the second electrode,
wherein the second layer comprises a first organic compound,
wherein the first organic compound has a first refractive index n1 with respect to light having the wavelength λ1, and
wherein the first refractive index n1 is more than or equal to 1.4 and less than or equal to 1.75.

2. The light-emitting device according to claim 1,
wherein the first spectrum ϕ1 has a full width at half maximum FWHM, and
wherein the full width at half maximum FWHM is greater than or equal to 10 nm and less than or equal to 35 nm.

3. The light-emitting device according to claim 1, wherein the second electrode comprises silver.

4. The light-emitting device according to claim 1, wherein the first organic compound is represented by General Formula (Gₑ₁2): 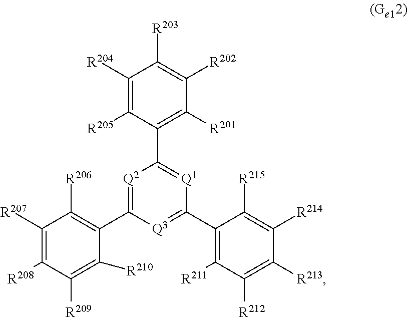
wherein two or three of Q¹ to Q³ are each a nitrogen atom,
wherein in the case where two of Q¹ to Q³ each represent a nitrogen atom, the remaining one of Q¹ to Q³ represents CH,
wherein at least one of R²⁰¹ to R²¹⁵ represents a phenyl group having a substituent,
wherein the others of R²⁰¹ to R²¹⁵ each independently represent any of hydrogen, an alkyl group having 1 to 6 carbon atoms, an alicyclic hydrocarbon group having 3 to 10 carbon atoms, a substituted or unsubstituted aromatic hydrocarbon group having 6 to 14 carbon atoms in a ring, and a substituted or unsubstituted pyridyl group,
wherein the phenyl group having a substituent has one or two substituents, and
wherein the substituents each independently represent any of an alkyl group having 1 to 6 carbon atoms, an alicyclic hydrocarbon group having 3 to 10 carbon atoms, and a substituted or unsubstituted aromatic hydrocarbon group having 6 to 14 carbon atoms in a ring.

5. The light-emitting device according to claim 4,
wherein the first organic compound comprises sp³ carbon atoms,
wherein the sp³ carbon atoms each form a bond with other atoms by sp³ hybrid orbitals, and
wherein a proportion of the sp³ carbon atoms in total carbon atoms contained in the first organic compound is higher than or equal to 10% and lower than or equal to 60%.

6. A light-emitting apparatus comprising:
the light-emitting device according to claim 1; and
at least one of a transistor and a substrate.

7. A display device comprising:
the light-emitting device according to claim 1; and
at least one of a transistor and a substrate.

8. A lighting device comprising:
the light-emitting apparatus according to claim 6; and
a housing.

9. An electronic device comprising:
the display device according to claim 7; and
at least one of a sensor, an operation button, a speaker, and a microphone.
